(19) United States
(12) Patent Application Publication
(10) Pub. No.: US 2023/0232664 A1
(43) Pub. Date: Jul. 20, 2023

(54) DISPLAY APPARATUS AND METHOD OF MANUFACTURING THE SAME

(71) Applicant: Samsung Display Co., Ltd., Yongin-si (KR)

(72) Inventors: Kwangmin KIM, Yongin-si (KR); Wonkyu KWAK, Yongin-si (KR)

(73) Assignee: Samsung Display Co., Ltd., Yongin-si (KR)

(21) Appl. No.: 18/097,743

(22) Filed: Jan. 17, 2023

(30) Foreign Application Priority Data
Jan. 18, 2022 (KR) 10-2022-0007475

(51) Int. Cl. H10K 59/122; H10K 59/12

(52) U.S. Cl. CPC H10K 59/122; H10K 59/1201

(57) ABSTRACT

A display apparatus and a method of manufacturing the same, the display apparatus including a first pixel electrode, a pixel-defining layer covering an edge of the first pixel electrode, and a separator disposed on the pixel-defining layer, and only a portion of a lower surface of the separator contacts the pixel-defining layer.

### CROSS-REFERENCE TO RELATED APPLICATION(S)

This application claims priority to and benefits of Korean Patent Application No. 10-2022-0007475 under 35 U.S.C. § 119, filed on Jan. 18, 2022, in the Korean Intellectual Property Office, the entire contents of which are incorporated herein by reference.

### BACKGROUND

### 1. Technical Field

One or more embodiments relate to a display apparatus and a method of manufacturing the same, and, to a display apparatus that displays high-quality images and a method of manufacturing the same.

### 2. Description of the Related Art

In general, a display apparatus such as an organic light-emitting display device may include a pixel electrode, an emission layer, and an opposite electrode, so that light emitted from the emission layer is emitted to the outside to display an image. Such a display apparatus emits light having a luminance corresponding to an electrical signal applied to the pixel electrode.

However, in the case of such a conventional display apparatus, the luminance of light emitted from an emission layer is not sufficient.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus that displays high-quality images and a method of manufacturing the same. However, this is an example, and the scope of the disclosure is not limited thereto.

Additional aspects will be set forth in part in the description which follows and, in part, will be apparent from the description, or may be learned by practice of the embodiments of the disclosure.

According to one or more embodiments, a display apparatus may include a first pixel electrode; a pixel-defining layer covering an edge of the first pixel electrode; and a separator disposed on the pixel-defining layer, wherein only a portion of a lower surface of the separator contacts the pixel-defining layer.

The display apparatus may further include a spacer disposed on the pixel-defining layer, wherein an entire lower surface of the spacer contacts the pixel-defining layer.

The display apparatus may further include a first common layer overlapping the first pixel electrode, the pixel-defining layer, and the separator in a plan view, the first common layer being discontinuous between the pixel-defining layer and the separator.

The first common layer may include a 1^{st}-1^{st} common layer overlapping the first pixel electrode in the plan view and a 1^{st}-2^{nd} common layer spaced apart from the 1^{st}-1^{st} common layer and overlapping the separator in the plan view.

The display apparatus may further include a 1^{st}-1^{st} emission layer overlapping the 1^{st}-1^{st} common layer in the plan view; a second common layer including a 2^{nd}-1^{st} common layer and a 2^{nd}-2^{nd} common layer spaced apart from the 2^{nd}-1^{st} common layer, wherein the 2^{nd}-1^{st} common layer overlaps the 1^{st}-1^{st} emission layer in the plan view, and the 2^{nd}-2^{nd} common layer overlaps the 1^{st}-2^{nd} common layer in the plan view, a 1^{st}-2^{nd} emission layer overlapping the 2^{nd}-1^{st} common layer in the plan view, and an opposite electrode overlapping the 1^{st}-2^{nd} emission layer and overlapping the separator in the plan view.

The display apparatus may further include a third common layer including a 3^{rd}-1^{st} common layer and a 3^{rd}-2^{nd} common layer spaced apart from the 3^{rd}-1^{st} common layer, wherein the 3^{rd}-1^{st} common layer may be disposed between the 1^{st}-2^{nd} emission layer and the opposite electrode, and the 3^{rd}-2^{nd} common layer may be disposed between the 2^{nd}-2^{nd} common layer and the opposite electrode.

The display apparatus may further include a third common layer integrally formed as a single body, the third common layer disposed between the 1^{st}-2^{nd} emission layer and the opposite electrode and disposed between the 2^{nd}-2^{nd} common layer and the opposite electrode.

The 2^{nd}-1^{st} common layer may include a first charge generating layer, and the 2^{nd}-2^{nd} common layer may include a second charge generating layer, and the second charge generating layer and the first charge generating layer may include a same material.

The 1^{st}-1^{st} common layer may not overlap the separator in the plan view.

An area of an upper surface of the separator may be greater than an area of the lower surface of the separator.

The display apparatus may further include an opposite electrode overlapping the first pixel electrode, the pixel-defining layer, and the separator in a plan view, and having a thickness greater than a distance between a portion of the lower surface of the separator that does not contact the pixel-defining layer and an upper surface of the pixel-defining layer.

According to one or more embodiments, a display apparatus may include a first pixel electrode; a pixel-defining layer covering an edge of the first pixel electrode; and a separator disposed on the pixel-defining layer, the separator having a first undercut at a lower portion of the separator in a direction to a center of the first pixel electrode.

The display apparatus may further include a spacer disposed on the pixel-defining layer, wherein an entire lower surface of the spacer contacts the pixel-defining layer.

The display apparatus may further include a first common layer overlapping the first pixel electrode, the pixel-defining layer, and the separator in the plan view, the first common layer being discontinuous between the pixel-defining layer and the separator.

The first common layer may include a 1^{st}-1^{st} common layer overlapping the first pixel electrode in the plan view and a 1^{st}-2^{nd} common layer spaced apart from the 1^{st}-1^{st} common layer and overlapping the separator in the plan view.

The 1^{st}-1^{st} common layer may not overlap the first undercut in the plan view.

The display apparatus may further include a 1^{st}-1^{st} emission layer overlapping the 1^{st}-1^{st} common layer in the plan view; a second common layer including a 2^{nd}-1^{st} common layer and a 2^{nd}-2^{nd} common layer spaced apart from the 2^{nd}-1^{st} common layer, wherein the 2^{nd}-1^{st} common layer overlaps the 1^{st}-1^{st} emission layer in the plan view, and the 2^{nd}-2^{nd} common layer overlaps the 1^{st}-2^{nd} common layer in the plan view, a 1^{st}-2^{nd} emission layer overlapping the 2^{nd}-1^{st} common layer in the plan view, and an opposite electrode overlapping the 1^{st}-2^{nd} emission layer and the separator in the plan view.

The first undercut may include a 1^{st}-1^{st} portion having a constant height, and a 1^{st}-2^{nd} portion connected to the 1^{st}-1^{st} portion and having a decreasing height.

The 1^{st}-1^{st} portion may be closer to the center of the first pixel electrode than the 1^{st}-2^{nd} portion.

The separator may encircle the first pixel electrode.

A part of the separator above the first undercut may have a cross-sectional area in a plane perpendicular to an upward direction, the cross-sectional area may increase in the upward direction.

The display apparatus may further include an opposite electrode overlapping the first pixel electrode, the pixel-defining layer, and the separator in a plan view, and the opposite electrode having a thickness greater than a height of the first undercut.

The display apparatus may further include a second pixel electrode spaced apart from the first pixel electrode, wherein the pixel-defining layer may cover an edge of the second pixel electrode, and the separator may be disposed between the first pixel electrode and the second pixel electrode and may have a second undercut at the lower portion of the separator in a direction to a center of the second pixel electrode.

The display apparatus may further include a first common layer including a 1^{st}-1^{st} common layer; a 1^{st}-2^{nd} common layer spaced apart from the 1^{st}-1^{st} common layer; and a 1^{st}-3^{rd} common layer spaced apart from the 1^{st}-2^{nd} common layer, the 1^{st}-1^{st} common layer overlapping the first pixel electrode in a plan view, the 1^{st}-2^{nd} common layer overlapping the separator in the plan view, the 1^{st}-3^{rd} common layer overlapping the second pixel electrode in the plan view.

The 1^{st}-3^{rd} common layer may not overlap the second undercut in the plan view.

The second undercut may include a 2^{nd}-1^{st} portion having a constant height, and a 2^{nd}-2^{nd} portion connected to the 2^{nd}-1^{st} portion and having a decreasing height.

The 2^{nd}-1^{st} portion may be closer to the center of the second pixel electrode than the 2^{nd}-2^{nd} portion.

The display apparatus may further include a third common layer including a 3^{rd}-1^{st} common layer and a 3^{rd}-2^{nd} common layer apart from the 3^{rd}-1^{st} common layer, the 3^{rd}-1^{st} common layer disposed between the 1^{st}-2^{nd} emission layer and the opposite electrode, the 3^{rd}-2^{nd} common layer disposed between the 2^{nd}-2^{nd} common layer and the opposite electrode.

The display apparatus may further include a third common layer integrally formed as a single body, the third common layer disposed between the 1^{st}-2^{nd} emission layer and the opposite electrode and disposed between the 2^{nd}-2^{nd} common layer and the opposite electrode.

The 2^{nd}-1^{st} common layer may include a first charge generating layer, and the 2^{nd}-2^{nd} common layer may include a second charge generating layer, and the second charge generating layer and the first charge generating layer may include a same material.

According to one or more embodiments, a method of manufacturing a display apparatus may include forming a pixel-defining layer covering an edge of a first pixel electrode; forming a sacrificial layer corresponding to the first pixel electrode, the sacrificial layer being disposed on an exposed portion of the first pixel electrode and the pixel-defining layer; forming a separator on the pixel-defining layer, the separator may cover at least a part of a portion of the sacrificial layer, the portion being disposed on the pixel-defining layer; and removing the sacrificial layer, so that the separator has a first undercut at a lower portion of the separator in a direction to a center of the first pixel electrode.

The method may further include forming a first common layer including a 1^{st}-1^{st} common layer and 1^{st}-2^{nd} common layer spaced apart from the 1^{st}-1^{st} common layer, the 1^{st}-1^{st} common layer may be disposed on the first pixel electrode and the 1^{st}-2^{nd} common layer may be disposed on the separator; forming a 1^{st}-1^{st} emission layer on the 1^{st}-1^{st} common layer; forming a second common layer including a 2^{nd}-1^{st} common layer and a 2^{nd}-2^{nd} common layer spaced apart from the 2^{nd}-1^{st} common layer, the 2^{nd}-1^{st} common layer may be disposed on the 1^{st}-1^{st} emission layer and the 2^{nd}-2^{nd} common layer may be disposed on the 1^{st}-2^{nd} common layer; forming a 1^{st}-2^{nd} emission layer on the 2^{nd}-1^{st} common layer; and forming an opposite electrode overlapping the 1^{st}-2^{nd} emission layer and the separator in a plan view.

The method may further include forming a third common layer including a 3^{rd}-1^{st} common layer and a 3^{rd}-2^{nd} common layer spaced apart from the 3^{rd}-1^{st} common layer, the 3^{rd}-1^{st} common layer may be disposed on the 1^{st}-2^{nd} emission layer and the 3^{rd}-2^{nd} common layer may be disposed on the 2^{nd}-2^{nd} common layer, wherein the forming of the opposite electrode comprises forming the opposite electrode on the third common layer.

The 2^{nd}-1^{st} common layer may include a first charge generating layer, and the 2^{nd}-2^{nd} common layer may include a second charge generating layer, and the second charge generating layer and the first charge generating layer may include a same material.

The forming of the opposite electrode may be forming the opposite electrode integrally formed as a single body with a thickness greater than a thickness of the sacrificial layer.

The forming of the sacrificial layer may comprise forming an IGZO layer, an ITO layer, or a ZTO layer.

The forming of the separator may include simultaneously forming the separator and a spacer having a lower surface, an entire area of the lower surface of the spacer contacting the pixel-defining layer.

These and/or other aspects will become apparent and more readily appreciated from the following description of the embodiments, taken in conjunction with the accompanying drawings.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic plan view of a display apparatus according to an embodiment;

FIGS. 2A and 2B are schematic plan views of a portion of a display apparatus according to an embodiment;

FIGS. 3A to 3D are schematic plan views of a portion of a display apparatus according to an embodiment;

FIG. 4 is a schematic cross-sectional view of the display apparatus of FIG. 2A taken along line I-I′ in FIG. 2A;

FIG. 5 is an enlarged schematic cross-sectional view of portion B of FIG. 4;

FIG. 6 is a schematic cross-sectional view of a portion of a display apparatus according to an embodiment;

FIG. 7 is an enlarged schematic cross-sectional view of portion C of FIG. 4;

FIGS. 8A and 8B are schematic plan views of a portion of a display apparatus according to an embodiment;

FIGS. 9A to 9D are schematic plan views of a portion of a display apparatus according to an embodiment;

FIG. 10 is a schematic cross-sectional view of the display apparatus of FIG. 6 taken along line II-II′ in FIG. 8A;

FIGS. 11 to 13 are views for explaining a method of manufacturing a display apparatus according to an embodiment;

FIG. 14 is a schematic cross-sectional view of a portion of a display apparatus according to an embodiment;

FIGS. 15 to 17 are views for explaining a method of manufacturing a display apparatus according to an embodiment;

FIG. 18 is a schematic cross-sectional view of a portion of a display apparatus according to an embodiment; and

FIG. 19 is a conceptual diagram of a portion of a display apparatus according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b or c” indicates only a, only b, only c, both a and b, both a and c, both b and c, all of a, b, and c, or variations thereof.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

Since the disclosure may have diverse modified embodiments, embodiments are illustrated in the drawings and are described in the detailed description. Advantages and features of the disclosure, and implementation methods thereof will be clarified through following embodiments described with reference to the accompanying drawings. The disclosure may, however, be embodied in many different forms and should not be construed as limited to the embodiments set forth herein.

Reference will now be made in detail to embodiments, examples of which are illustrated in the accompanying drawings, wherein like reference numerals refer to like elements throughout, and repeated description thereof will be omitted.

It will be understood that when a layer, region, or component is referred to as being “formed on” another layer, region, or component, it can be directly or indirectly formed on the other layer, region, or component. For example, intervening layers, regions, or components may be present.

Sizes of components in the drawings may be exaggerated for convenience of explanation. In other words, since sizes and thicknesses of components in the drawings are arbitrarily illustrated for convenience of description, the following embodiments are not limited thereto.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the following embodiments, an x-axis, a y-axis, and a z-axis are not limited to three axes on an orthogonal coordinate system and may be broadly understood. For example, the x-axis, the y-axis, and the z-axis may be perpendicular to one another or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

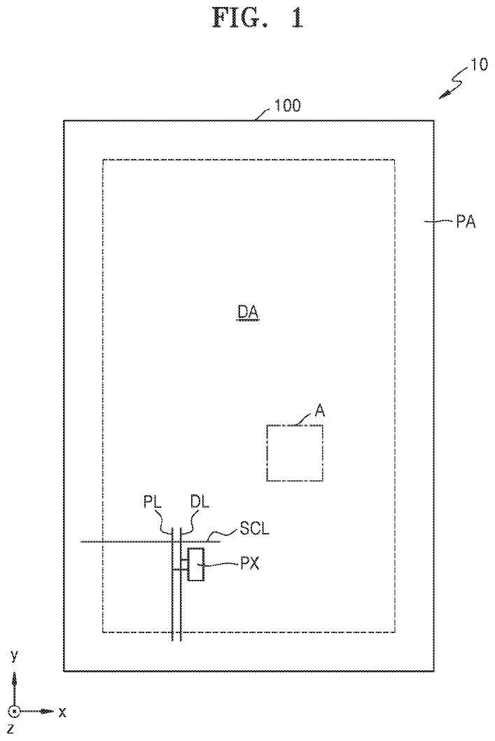

FIG. 1 is a schematic plan view of a display apparatus according to an embodiment. As shown in FIG. 1, the display apparatus according to an embodiment may include a display panel 10. Such a display apparatus may be any type as long as it may include the display panel 10. For example, the display apparatus may be a variety of devices, such as a smartphone, tablet, laptop, television or billboard.

The display panel 10 may include a display area DA and a peripheral area PA outside the display area DA. FIG. 1 illustrates that the display area DA has a rectangular shape. However, the disclosure is not limited thereto. The display area DA may have various shapes, such as a circular shape, an elliptical shape, other polygonal shape, or a specific shape. It is to be understood that the shapes disclosed herein may also include shapes substantial to the shapes disclosed herein.

The display area DA is a portion for displaying an image, and pixels PX may be arranged or disposed in the display area DA. Each pixel PX may include a display element such as an organic light-emitting diode. Each pixel PX may emit, for example, red, green, or blue light. The pixel PX may be connected to a pixel circuit including a thin-film transistor (TFT), a storage capacitor, and the like within the spirit and the scope of the disclosure. Such a pixel circuit may be connected to a scan line SCL that transmits a scan signal, a data line DL that intersects the scan line SCL and transmits a data signal, a driving voltage line PL that supplies a driving voltage, and the like within the spirit and the scope of the disclosure. The scan line SCL may extend in an x direction, and the data line DL and the driving voltage line PL may extend in a y direction.

The pixel PX may emit light having a luminance corresponding to an electrical signal from an electrically connected pixel circuit. The display area DA may display an image through light emitted from the pixel PX. For reference, the pixel PX may be defined as a light emitting area emitting light of any one color from among red, green, and blue as described above.

The peripheral area PA is an area in which the pixels PX are not arranged, and may be an area in which an image is not displayed. Power supply wiring for driving the pixel PX may be located (or disposed) in the peripheral area PA. A printed circuit board including a driving circuit unit or a terminal unit to which a driver IC is connected may be arranged in the peripheral area PA.

For reference, because the display panel 10 may include the substrate 100, it may be said that the substrate 100 has such a display area DA and a peripheral area PA.

Hereinafter, as a display apparatus according to an embodiment, an organic light-emitting display device will be described. However, the display apparatus of the disclosure is not limited thereto. For example, the display apparatus of the disclosure may be an inorganic light-emitting display (or an inorganic EL display) or a quantum dot light-emitting display.

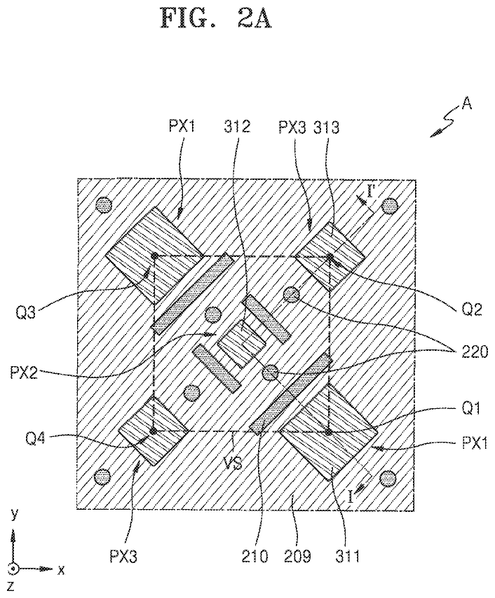

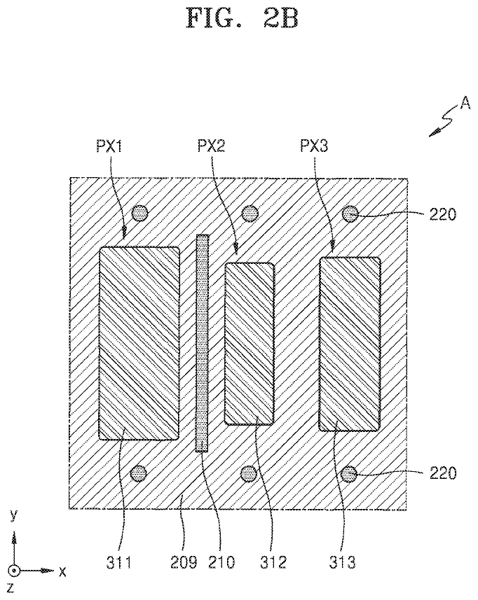

FIG. 2A is a schematic plan view illustrating a portion of a display apparatus according to an embodiment. FIG. 2A may be an enlarged schematic plan view of portion A of FIG. 1.

As shown in FIG. 2A, the display apparatus may include pixels PX1, PX2, and PX3. The pixels PX1, PX2, and PX3 may include the first pixel PX1, the second pixel PX2, and the third pixel PX3 emitting light of different colors, respectively. The first pixel PX1 may be a pixel emitting blue light, the second pixel PX2 may be a pixel emitting green light, and the third pixel PX3 may be a pixel emitting red light. However, the disclosure is not limited thereto. For example, the first pixel PX1 may be a pixel emitting green light, the second pixel PX2 may be a pixel emitting red light, and the third pixel PX3 may be a pixel emitting blue light.

Each of the first pixel PX1, the second pixel PX2, and third pixel PX3 may have a polygonal shape when viewed from a direction perpendicular to the substrate 100 (a z-axis direction). FIG. 2A illustrates that each of the first pixel PX1, the second pixel PX2, and the third pixel PX3 has a rectangular shape when viewed from a direction perpendicular to the substrate 100 (the z-axis direction), in more detail, a rectangular shape with rounded corners. However, the disclosure is not limited thereto. For example, each of the first pixel PX1, the second pixel PX2, and the third pixel PX3 may have a circular shape or an elliptical shape when viewed from a direction perpendicular to the substrate 100 (the z-axis direction).

The sizes, for example, areas, of the first pixel PX1, the second pixel PX2, and the third pixel PX3 may be different from each other. For example, the area of the second pixel PX2 may be smaller than those of the first pixel PX1 and the third pixel PX3. However, the disclosure is not limited thereto. For example, areas of the second pixel PX2 and the third pixel PX3 may be substantially the same.

The first pixel PX1 may include a first pixel electrode 311, the second pixel PX2 may include a second pixel electrode 312, and the third pixel PX3 may include a third pixel electrode 313. A pixel-defining layer 209 covers edges of the first pixel electrode 311, the second pixel electrode 312, and the third pixel electrode 313, respectively. For example, the pixel-defining layer 209 may have an opening exposing the center of the third pixel electrode 313, an opening exposing the center of the first pixel electrode 311, and an opening exposing the center of the second pixel electrode 312. The above-described sizes of the first pixel PX1, the second pixel PX2, and the third pixel PX3 may refer to the size of a light emitting area of a display element implementing each pixel. Such a light emitting area may be defined by an opening of the pixel-defining layer 209.

A separator 210 and a spacer 220 are on the pixel-defining layer 209.

The first pixel PX1, the second pixel PX2, and the third pixel PX3 may be arranged in a PENTILE™ manner. For example, assuming a virtual quadrangle VS centered on the center of the second pixel PX2, the first pixel PX1 may be at a first vertex Q1, and the third pixel PX3 may be at a second vertex Q2 adjacent to the first vertex Q1. The first pixel PX1 may be at a third vertex Q3 symmetrical to the first vertex Q1 with respect to the center of the virtual quadrangle VS, and the third pixel PX3 may be at a fourth vertex Q4 symmetrical to the second vertex Q2 with respect to the center of the virtual quadrangle VS. The virtual quadrangle VS may have a square shape. The first pixel PX1 and the third pixel PX3 may be alternately arranged in the x-axis direction and the y-axis direction intersecting the x-axis direction. In other words, the set of first pixels PX1, second pixels PX2, and third pixels PX3 arranged as shown in FIG. 2A may be repeatedly located in the x-axis direction and repeatedly located in the y-axis direction. Accordingly, the first pixel PX1 may be surrounded by the second pixels PX2 and the third pixels PX3.

The separator 210 may be located to correspond between the first pixel PX1 and the second pixel PX2 as shown in FIG. 2A. For example, the separator 210 may be located to correspond between the first pixel electrode 311 and the second pixel electrode 312. The display apparatus according to an embodiment may include separators 210. For example, as shown in FIG. 2A, the separator 210 may also be located between the second pixel PX2 and the third pixel PX3. The spacer 220 may also be located to correspond between pixels. For example, the spacer 220 may be located to correspond between the first pixel electrode 311 and the second pixel electrode 312. The display apparatus according to an embodiment may include spacers 220. For example, as shown in FIG. 2A, the spacer 220 may also be located between the second pixel PX2 and the third pixel PX3. Here, the expression “correspond between” means “correspond to a space between”.

The disclosure is not limited to arranging the first pixel PX1, the second pixel PX2, and the third pixel PX3 in a PENTILE™ manner. For example, as shown in FIG. 2B, which is a schematic plan view illustrating a portion of a display apparatus according to an embodiment, the first pixel PX1, the second pixel PX2, and the third pixel PX3 may be arranged in a stripe manner. For example, the first pixel PX1, the second pixel PX2, and the third pixel PX3 may be sequentially arranged in the x-axis direction. However, by way of example, the pixels may be arranged in a mosaic manner.

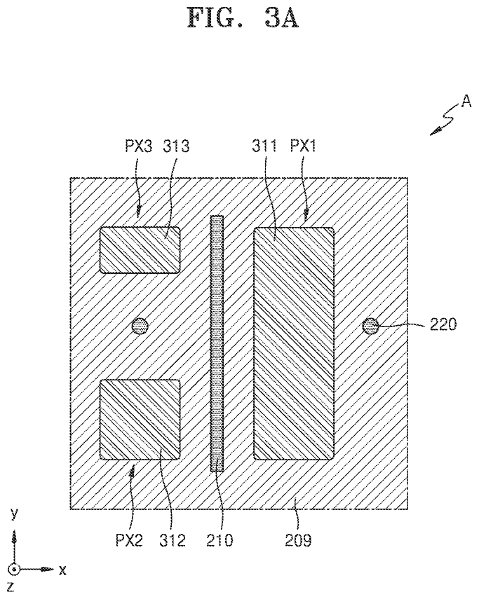

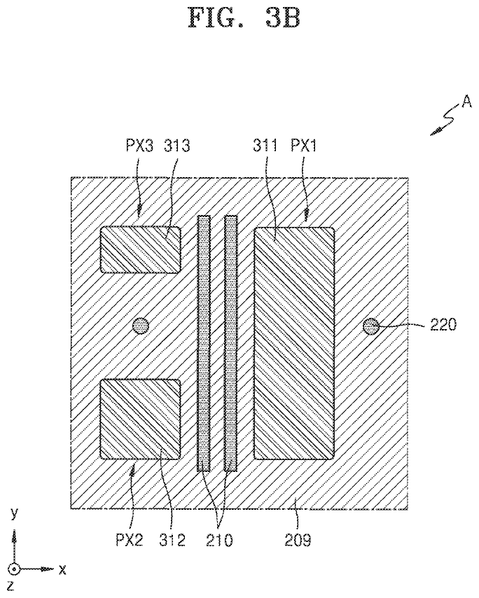

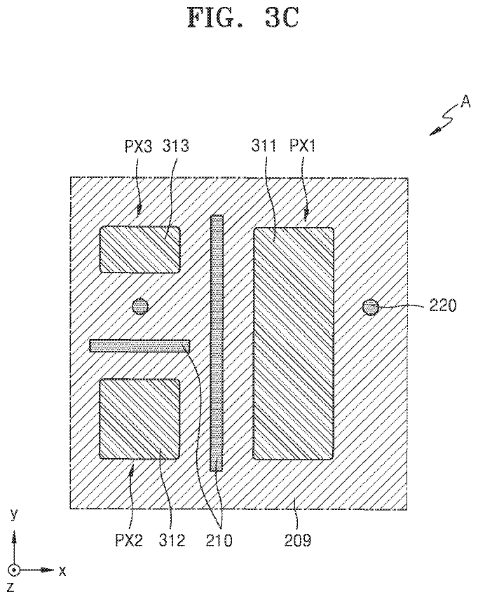

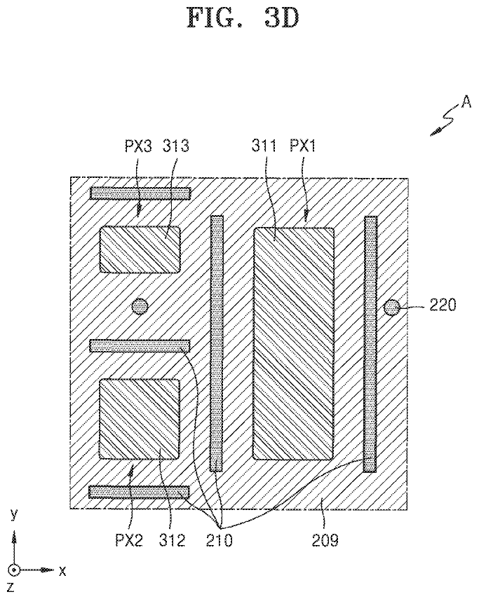

As shown in FIGS. 3A to 3D, which are schematic plan views illustrating a portion of a display apparatus according to an embodiment, the first pixel PX1, the second pixel PX2, and the third pixel PX3 may be arranged in a S-stripe manner. As shown in FIG. 3A, for example, the separator 210 may be located to correspond between the second pixel PX2 emitting green light, the third pixel PX3 emitting red light, and the first pixel PX1 emitting blue light. However, the spacer 220 may be located to correspond to between the second pixel PX2 and the third pixel PX3. As shown in FIG. 3B, two separators 210 may be located between the second pixel PX2 and the third pixel PX3 and the first pixel PX1.

As shown in FIG. 3C, the separator 210 may be located to correspond between the second pixel PX2 and the third pixel PX3 and the first pixel PX1, and may also be located between the second pixel PX2 and the third pixel PX3. Because the separator 210 is between the third pixel PX3 and the second pixel PX2 (located in a −y direction), the separator 210 may not be located between the third pixel PX3 and the second pixel PX2 (not shown and located in a +y direction), and may also not be located between the second pixel PX2 and the third pixel PX3 (not shown and located in the −y direction). As shown in FIG. 3D, the separators 210 may be on both sides (in +x and −x directions) of the first pixel PX1, or may be located between the second pixels PX2 and the third pixels PX3 arranged along the y-axis direction.

However, the disclosure is not limited thereto. For example, the separator 210 may encircle the first pixel PX1 in a plan view. For example, the separator 210 may encircle the first pixel electrode 311 in a plan view.

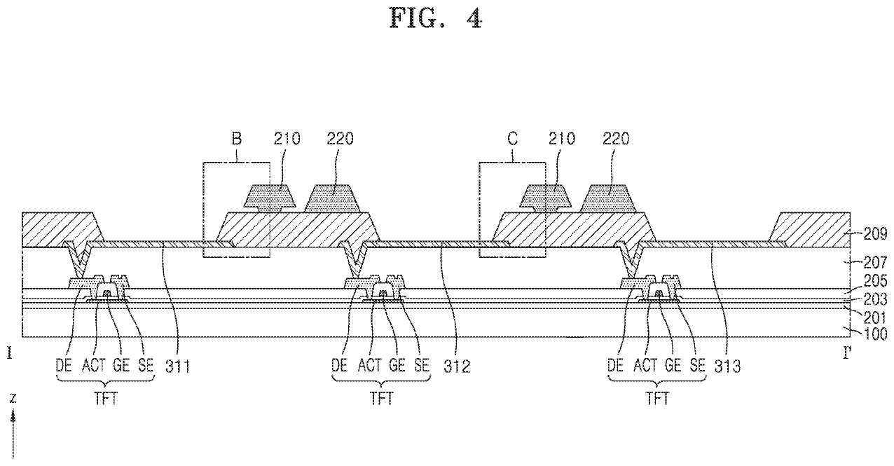

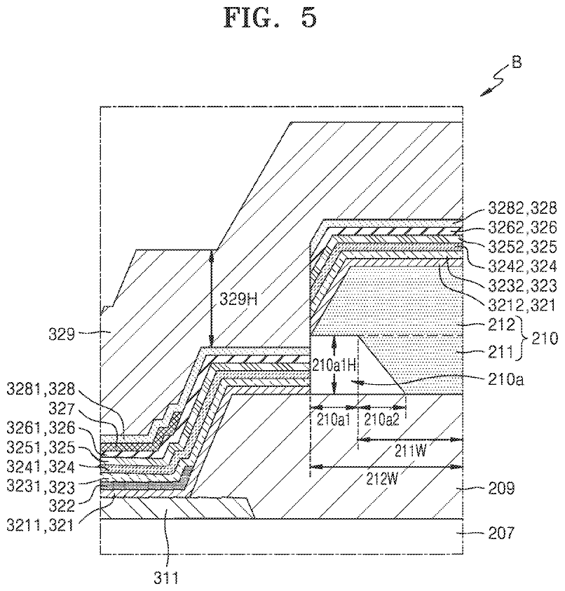

FIG. 4 is a schematic cross-sectional view of the display apparatus of FIG. 2A taken along line I-I′ in FIG. 2A, and FIG. 5 is an enlarged schematic cross-sectional view of portion B of FIG. 4. In FIG. 4, some of the components shown in FIG. 5 may be omitted for convenience of illustration.

As shown in FIG. 4, the display apparatus according to an embodiment may include organic light-emitting diodes disposed on the substrate 100.

The substrate 100 may include glass, metal, or a polymer resin. In case that at least a portion of the display apparatus is bent or the display apparatus has a flexible characteristic, the substrate 100 needs to have a flexible or bendable characteristic. The substrate 100 may include, for example, a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including two layers including the polymer resin, and a barrier layer including an inorganic material such as silicon oxide, silicon nitride, or silicon oxynitride between the two layers, and various modifications thereof may be made. Furthermore, if the substrate 100 is not bent, the substrate 100 may include glass or the like within the spirit and the scope of the disclosure.

A buffer layer 201 may be on the substrate 100 to prevent or minimize penetration of impurities or moisture from the substrate 100 or from a lower portion of the substrate 100, and may planarize an upper surface of the substrate 100. The buffer layer 201 may include an inorganic material such as oxide, nitride, or oxynitride. For example, the buffer layer 201 may include silicon oxide, silicon nitride, or silicon oxynitride.

A thin-film transistor TFT may be on the buffer layer 201. The thin-film transistor TFT may include a semiconductor layer ACT, a gate electrode GE, a source electrode SE, and a drain electrode DE. The thin-film transistor TFT may be electrically connected to a corresponding organic light-emitting diode to drive the organic light-emitting diode.

The semiconductor layer ACT may be disposed on the buffer layer 201 and may include amorphous silicon or polysilicon. If necessary, the semiconductor layer ACT may include an oxide semiconductor. In the latter case, the semiconductor layer ACT may include an oxide of at least one of indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer ACT may include a channel area and a source area and a drain area doped with impurities.

The gate electrode GE may include a metal, an alloy, a conductive metal oxide, or a transparent conductive material. For example, the gate electrode GE may include silver (Ag), alloy containing Ag, molybdenum (Mo), alloy containing Mo, aluminum (Al), alloy containing Al, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The gate electrode GE may have a multilayer structure. For example, the gate electrode GE may have a two-layer structure of Mo/Al or a three-layer structure of Mo/Al/Mo.

The source electrode SE and the drain electrode DE may also include a metal, an alloy, a conductive metal oxide, or a transparent conductive material. For example, the source electrode SE and the drain electrode DE may include Ag, alloy containing Ag, Mo, alloy containing Mo, Al, alloy containing Al, AlN, W, WN, Cu, Ni, Cr, CrN, Ti, Ta, Pt, Sc, ITO, or IZO. The source electrode SE and the drain electrode DE may have a multilayer structure. For example, the source electrode SE and the drain electrode DE may have a two-layer structure of Ti/Al or a three-layer structure of Ti/Al/Ti.

In order to secure insulation between the semiconductor layer ACT and the gate electrode GE, a gate insulating layer 203 may be interposed between the semiconductor layer ACT and the gate electrode GE. The gate insulating layer 203 may include an inorganic insulating layer such as silicon oxide, silicon nitride, silicon oxynitride, or aluminum oxide. An interlayer insulating layer 205 may be disposed on the gate electrode GE, and the source electrode SE and the drain electrode DE may be disposed on the interlayer insulating layer 205. The interlayer insulating layer 205 may include an inorganic insulating layer such as silicon oxide, silicon nitride, silicon oxynitride, or aluminum oxide. Because the gate insulating layer 203 and the interlayer insulating layer 205 are insulating layers including an inorganic material, they may be formed through atomic layer deposition (ALD). This is the same in the embodiments and modifications thereof to be described later.

Although FIG. 4 shows that the thin-film transistor TFT has both the source electrode SE and the drain electrode DE, the disclosure is not limited thereto. For example, one pixel circuit may include thin-film transistors, and thus, a drain area of the first thin-film transistor may be electrically connected to a source area of the second thin-film transistor. The drain area of the first thin-film transistor may be integrally formed as a single body with the source area of the second thin-film transistor. The first thin-film transistor may not have the drain electrode DE, and the second thin-film transistor may not have the source electrode SE.

A planarization layer 207 may be disposed on the thin-film transistor TFT. In order to provide a flat top surface, after the planarization layer 207 is formed, chemical mechanical polishing may be performed on an upper surface of the planarization layer 207. The planarization layer 207 may include an organic insulating material. For example, the planarization layer 207 may include photoresist, benzocyclobutene (BCB), polyimide, hexamethyldisiloxane (HMDSO), polymethylmethacrylate (PMMA), polystyrene, a polymer derivative having a phenol-based group, an acrylic polymer, an imide polymer, an aryl ether polymer, an amide polymer, a fluorine polymer, a p-xylene polymer, a vinyl alcohol-based polymer, or a mixture thereof Although the planarization layer 207 is shown as a single layer in FIG. 4, the planarization layer 207 may have a multilayer structure if necessary.

An organic light-emitting diode may be on the planarization layer 207. The organic light-emitting diode may include a pixel electrode, an intermediate layer including an emission layer, and an opposite electrode. FIG. 4 illustrates that the first pixel electrode 311, the second pixel electrode 312, and the third pixel electrode 313 are disposed on the planarization layer 207. The first pixel electrode 311, the second pixel electrode 312, and the third pixel electrode 313 may be arranged to be apart from each other.

The first pixel electrode 311, the second pixel electrode 312, and the third pixel electrode 313 may be a (semi)transmissive electrode or a reflective electrode. For example, each of the first pixel electrode 311, the second pixel electrode 312, and the third pixel electrode 313 may include a reflective layer including Ag, Mg, Al, Pt, Pd, Au, Ni, Nd, Ir, Cr, and a compound thereof, and a transparent or translucent electrode layer disposed on the reflective layer. The transparent or translucent electrode layer may include at least one of ITO, IZO, zinc oxide (ZnOₓ, for example, ZnO), indium oxide (In₂O₃), indium gallium oxide (IGO), and aluminum zinc oxide (AZO). For example, the first pixel electrode 311, the second pixel electrode 312, and the third pixel electrode 313 may have a three-layer structure of ITO/Ag/ITO.

The pixel-defining layer 209 may be disposed on the planarization layer 207. The pixel-defining layer 209 covers edges of the first pixel electrode 311, the second pixel electrode 312, and the third pixel electrode 313, respectively. Accordingly, a pixel-defining layer 209 may prevent generation of an arc on the edges of the first pixel electrode 311, the second pixel electrode 312, and the third pixel electrode 313 by increasing a distance between the edges of the first pixel electrode 311, the second pixel electrode 312, and the third pixel electrode 313 and an opposite electrode 329 on the first pixel electrode 311, the second pixel electrode 312, and the third pixel electrode 313. The pixel-defining layer 209 may include at least one organic insulating material from among polyimide, polyamide, acrylic resin, BCB, and phenolic resin, and may be formed by spin coating or the like within the spirit and the scope of the disclosure.

In an embodiment, the pixel-defining layer 209 may include a light blocking material. The light blocking material may include resins or pastes containing carbon black, carbon nanotubes, or black dye, metal particles such as nickel, aluminum, molybdenum, and alloys thereof, metal oxide particles (for example, chromium oxide), or metal nitride particles (for example, chromium nitride). By disposing the pixel-defining layer 209 including the light blocking material, reflection of external light by the metal structures disposed under or below the pixel-defining layer 209 may be reduced.

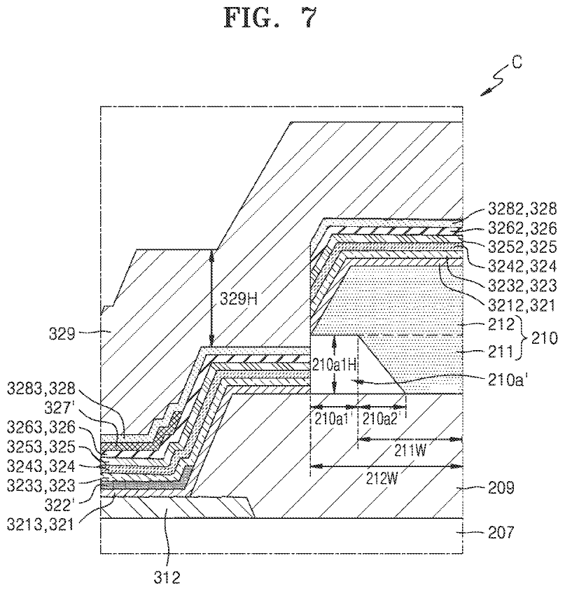

The separator 210 and the spacer 220 are on the pixel-defining layer 209. As shown in FIGS. 4 and 5, the separator 210 has a first undercut 210a at a lower portion of the separator 210 in a direction to a center of the first pixel electrode 311, so that only a portion of a lower surface of the separator 210 in a direction to the pixel-defining layer 209 contacts the pixel-defining layer 209. Unlike the separator 210, an entire lower surface of the spacer 220 in the direction to the pixel-defining layer 209 is in contact with the pixel-defining layer 209. As shown in FIG. 4, another separator 210 may also have a second undercut 210a′ (see FIG. 7) similar to the first undercut 210a at a lower portion of the separator 210 in a direction toward the center of the second pixel electrode 312. The description of the first undercut 210a, which will be described later, may also be applied to the second undercut 210a′. The separator 210 and the spacer 220 may include a same material or a similar material. The separator 210 and the spacer 220 may include at least one organic insulating material from among polyimide, polyamide, acrylic resin, BCB, and phenolic resin, and may be formed by spin coating or the like within the spirit and the scope of the disclosure.

Because the separator 210 has the first undercut 210a, only a portion of a lower surface of the separator 210 in the direction to the pixel-defining layer 209 contacts the pixel-defining layer 209. For example, the separator 210 may be understood to include a first portion 211 and a second portion 212. At this time, the first portion 211 and the second portion 212 are one body. The first portion 211 is a portion in contact with the pixel-defining layer 209 and has a first width (double that of 211W indicated in FIG. 5). The second portion 212 is a portion located on the first portion 211 and has a second width (double that of 212W indicated in FIG. 5) greater than the first width. Due to a difference between the first width of the first portion 211 and the second width of the second portion 212, the separator 210 may have the first undercut 210a as described above. For reference, a central axis of the first portion 211 and a central axis of the second portion 212 may coincide, and accordingly, the separator 210 may have an undercut which is almost symmetrical to the first undercut 210a with respect to the central axis of the first portion 211, in a cross-sectional view. This may be understood that the first undercut 210a revolves around the separator 210 in a plan view.

An opposite electrode 329 is on the first pixel electrode 311, the second pixel electrode 312, and the third pixel electrode 313. The opposite electrode 329 may be a transparent electrode or a reflective electrode. For example, the opposite electrode 329 may be a transparent electrode or a translucent electrode, and may include a metal thin-film, which has a small work function, including Li, Ca, lithium fluoride (LiF), Al, Ag, Mg, or a compound thereof. The opposite electrode 329 may further include a transparent conductive oxide (TCO) layer such as ITO, IZO, ZnOₓ (for example, ZnO), or In₂O₃ disposed on the metal thin film. The opposite electrode 329 may be integrally formed as a single body over the entire display area DA.

An intermediate layer including an emission layer may be interposed between the first pixel electrode 311, the second pixel electrode 312, and the third pixel electrode 313 and the opposite electrode 329. Hereinafter, this will be described.

A first common layer 321 is disposed on the first pixel electrode 311, the pixel-defining layer 209, the separator 210, and the spacer 220. As shown in FIG. 5, the first common layer 321 may be discontinuous between the pixel-defining layer 209 and the separator 210. In more detail, the first common layer 321 may be discontinuous at an edge of the separator 210 in a direction to the first pixel electrode 311. Accordingly, the first common layer 321 may include a 1^{st}-1^{st} common layer 3211 and a 1^{st}-2^{nd} common layer 3212. The 1^{st}-1^{st} common layer 3211 may be on the first pixel electrode 311, and the 1^{st}-2^{nd} common layer 3212 may be on the separator 210. The 1^{st}-1^{st} common layer 3211 may be on a portion of the pixel-defining layer 209 as shown in FIG. 5 as well as on the first pixel electrode 311. The first common layer 321 may have a portion disposed over the spacer 220, and the portion of the first common layer 321 may be integrally formed as a single body with the 1^{st}-1^{st} common layer 3211. This is because the spacer 220 does not have an undercut so that the entire lower surface of the spacer 220 is in contact with the pixel-defining layer 209.

The first common layer 321 may be, for example, a hole injection layer (HIL) or a hole transport layer (HTL), or may have a structure in which the hole injection layer and the hole transport layer may be stacked each other. The 1^{st}-2^{nd} common layer 3212 may include a same material or a similar material as that of the 1^{st}-1^{st} common layer 3211 and may have a same layer structure as that of the 1^{st}-1^{st} common layer 3211. Because the separator 210 has the first undercut 210a as described above, the 1^{st}-2^{nd} common layer 3212 disposed over the separator 210 is apart from the 1^{st}-1^{st} common layer 3211 disposed over the first pixel electrode 311.

A 1^{st}-1^{st} emission layer 322 is on the 1^{st}-1^{st} common layer 3211. The 1^{st}-1^{st} emission layer 322 may emit, for example, blue light.

A second common layer may include a 2^{nd}-1^{st} common layer and a 2^{nd}-2^{nd} common layer apart from the 2^{nd}-1^{st} common layer. The 2^{nd}-1^{st} common layer is disposed over the 1^{st}-1^{st} emission layer 322 and the 2^{nd}-2^{nd} common layer is disposed over the 1^{st}-2^{nd} common layer 3212. The second common layer may also have a portion disposed over the spacer 220, and the portion disposed over the spacer 220 may be integrally formed as a single body with the 2^{nd}-1^{st} common layer. This is because the spacer 220 does not have an undercut so that the entire lower surface of the spacer 220 is in contact with the pixel-defining layer 209.

The second common layer may have a multilayer structure. FIG. 5 shows that the 2^{nd}-1^{st} common layer may include an electron transport layer 3231, an electron generating layer 3241, a hole generating layer 3251, and a hole transport layer 3261. The 2^{nd}-1^{st} common layer may further include an electron injection layer interposed between the electron transport layer 3231 and the electron generation layer 3241, and may further include a hole injection layer interposed between the hole generating layer 3251 and the hole transport layer 3261. Similarly, FIG. 5 shows that the 2nd-2nd common layer may include an electron transport layer 3232, an electron generating layer 3242, a hole generating layer 3252, and a hole transport layer 3262. The 2^{nd}-2^{nd} common layer may further include an electron injection layer interposed between the electron transport layer 3232 and the electron generation layer 3242, and may further include a hole injection layer interposed between the hole generating layer 3252 and the hole transport layer 3262. For example, an electron transport layer 323 may include the electron transport layer 3231 and the electron transport layer 3232 apart from each other, an electron generating layer 324 may include the electron generating layer 3241 and the electron generating layer 3242 apart from each other, a hole generating layer 325 may include the hole generating layer 3251 and the hole generating layer 3252 that are apart from each other, and a hole transport layer 326 may include the hole transport layer 3261 and the hole transport layer 3262 apart from each other.

As described above, the 2^{nd}-1^{st} common layer may be on the 1^{st}-1^{st} emission layer 322, and the 2^{nd}-2^{nd} common layer may be on the 1^{st}-2^{nd} common layer 3212. The 2^{nd}-1^{st} common layer may also be on a portion of the 1^{st}-1^{st} common layer 3211 outside the 1^{st}-1^{st} emission layer 322 as shown in FIG. 5 as well as on the 1^{st}-1^{st} emission layer 322. The 2^{nd}-2^{nd} common layer may include a same material or a similar material as that of the 2^{nd}-1^{st} common layer and may have a same layer structure as that of the 2^{nd}-1^{st} common layer. Because the separator 210 has the first undercut 210a as described above, the 2nd-2nd common layer disposed on the separator 210 is apart from the 2^{nd}-1^{st} common layer on the first pixel electrode 311.

A 1^{st}-2^{nd} emission layer 327 is on the 2^{nd}-1^{st} common layer. The 1^{st}-2^{nd} emission layer 327 may emit light belonging to the same wavelength band as that of the 1^{st}-1^{st} emission layer 322. For example, the 1^{st}-2^{nd} emission layer 327 and the 1^{st}-1^{st} emission layer 322 may emit blue light.

A third common layer 328 may include a 3^{rd}-1^{st} common layer 3281 and a 3^{rd}-2^{nd} common layer 3282. The 3^{rd}-1^{st} common layer 3281 may be interposed between the 1^{st}-2^{nd} emission layer 327 and the opposite electrode 329, and the 3^{rd}-2^{nd} common layer 3282 may be interposed between the 2^{nd}-2^{nd} common layer and the opposite electrode 329. The 3^{rd}-1^{st} common layer 3281 may be disposed over not only the 1^{st}-2^{nd} emission layer 327 but also a portion of the 2^{nd}-1^{st} common layer as shown in FIG. 5. Here, the portion of the 2^{nd}-1^{st} common layer is outside the 1^{st}-2^{nd} emission layer 327. The third common layer 328 may have a portion disposed over the spacer 220, and the portion of the third common layer 328 may be integrally formed as a single body with the 3^{rd}-1^{st} common layer 3281. This is because the spacer 220 does not have an undercut so that the entire lower surface of the spacer 220 is in contact with the pixel-defining layer 209.

The third common layer 328 may be, for example, an electron injection layer (EIL) or an electron transport layer (ETL), and may have a structure in which the electron injection layer and the electron transport layer may be stacked each other. The 3^{rd}-2^{nd} common layer 3282 may include a same material or a similar material as that of the 3^{rd}-1^{st} common layer 3281 and may have a same layer structure as that of the 3^{rd}-1^{st} common layer 3281. Because the separator 210 has the first undercut 210a as described above, the 3^{rd}-2^{nd} common layer 3282 disposed over the separator 210 is apart from the 3^{rd}-1^{st} common layer 3281 disposed over the first pixel electrode 311.

In the case of the display apparatus according to an embodiment, as described above, the 2^{nd}-1^{st} common layer may include the electron generating layer 3241 and the hole generating layer 3251, as a first charge generating layer. The 1^{st}-1^{st} emission layer 322 is below the first charge generating layer, and the 1^{st}-2^{nd} emission layer 327 is disposed over the first charge generating layer. Accordingly, because light is emitted not only by the 1^{st}-1^{st} emission layer 322 but also by the 1^{st}-2^{nd} emission layer 327 on the first pixel electrode 311, the first pixel PX1 may emit light of high luminance. The 2^{nd}-2^{nd} common layer also has the electron generating layer 3242 and the hole generating layer 3252, as a second charge generating layer.

In order to emit light by the 1^{st}-1^{st} emission layer 322 and the 1^{st}-2^{nd} emission layer 327, as described above, the electron generating layer 3241 and the hole generating layer 3251, as the first charge generating layer, need to be interposed between the 1^{st}-1^{st} emission layer 322 and the 1^{st}-2^{nd} emission layer 327. The electron generating layer 3241 generates electrons and supplies them to the 1^{st}-1^{st} emission layer 322 so that light is emitted from the 1^{st}-1^{st} emission layer 322 receiving holes from the first pixel electrode 311, and the hole generating layer 3251 generates holes and supplies them to the 1^{st}-2^{nd} emission layer 327 so that light is emitted from the 1^{st}-2^{nd} emission layer 327 receiving electrons from the opposite electrode 329.

In case that the first charge generating layer including the electron generating layer 3241 and the hole generating layer 3251 may be integral with the first pixel PX1 and the second pixel PX2, electrons or holes generated in a portion of the first charge generating layer above the first pixel electrode 311 move laterally along the first charge generating layer, so that unintentional light emission may occur in the second pixel PX2. This may eventually cause a problem in that the quality of a displayed image is deteriorated.

However, in the case of the display apparatus according to an embodiment, the separator 210 has the first undercut 210a as described above. Accordingly, the second charge generating layer included in the 2^{nd}-2^{nd} common layer on the separator 210 is apart from the first charge generating layer included in the 2^{nd}-1^{st} common layer on the first pixel electrode 311. As a result, the movement of electrons or holes generated in the portion of the first charge generating layer above the first pixel electrode 311 to the second pixel PX2 may be effectively prevented or minimized, so that a display apparatus displaying a high-quality image may be implemented.

As shown in FIG. 5, the first undercut 210a may include a 1^{st}-1^{st} portion 210a1 having a constant height, and a 1^{st}-2^{nd} portion 210a2 connected to the 1^{st}-1^{st} portion 210a1 and having a decreasing height. The 1^{st}-1^{st} portion 210a1 is relatively closer to the center of the first pixel electrode 311 than the 1^{st}-2^{nd} portion 210a2.

The first undercut 210a separates the 1^{st}-1^{st} common layer 3211 and the 1^{st}-2^{nd} common layer 3212, and accordingly, the 1^{st}-1^{st} common layer 3211 does not overlap the first undercut 210a in a plan view. For example, the 1^{st}-1^{st} common layer 3211 does not overlap the separator 210 in a plan view, in more detail, the second portion 212 of the separator 210. Because the first undercut 210a is to prevent electrons or holes generated in the portion of the first charge generating layer above the first pixel electrode 311 from moving to the second pixel PX2, if necessary, the first undercut 210a may encircle the first pixel electrode 311. Because the first undercut 210a is included in the separator 210, in order for the first undercut 210a to go around the first pixel electrode 311, the separator 210 may have a portion that goes around the first pixel electrode 311.

The first undercut 210a separates the 2^{nd}-1^{st} common layer including the first charge generating layer and the 2^{nd}-2^{nd} common layer including the second charge generating layer. Accordingly, a height 210a1H of the 1^{st}-1^{st} portion 210a1 having a constant height of the first undercut 210a needs to be greater than or equal to a height from an upper surface of the pixel-defining layer 209 to an upper surface of the 2^{nd}-1^{st} common layer. For example, the height 210a1H of the first portion 211 of the separator 210 needs to be greater than or equal to the height from the upper surface of the pixel-defining layer 209 to the upper surface of the 2^{nd}-1^{st} common layer.

The opposite electrode 329 may be disposed on the first pixel electrode 311, the second pixel electrode 312, the pixel-defining layer 209, the separator 210, and the spacer 220. The opposite electrode 329 may be integrally formed as a single body over pixels. It is necessary to prevent the portion of the opposite electrode 329 above the first pixel electrode 311 from being apart from a portion of the opposite electrode 329 above the second pixel electrode 312 by the first undercut 210a. Accordingly, in order to ensure that the opposite electrode 329 may be integrally formed as a single body over the pixels, a thickness 329H of the opposite electrode 329 may be greater than a distance between a portion of a lower surface of the separator 210 that is not in contact with the pixel-defining layer 209 and the upper surface of the pixel-defining layer 209. For example, the thickness 329H of the opposite electrode 329 may be greater than the height 210a1H of the first undercut 210a. For example, the thickness 329H of the opposite electrode 329 may be greater than the height 210a1H of the first portion 211 of the separator 210.

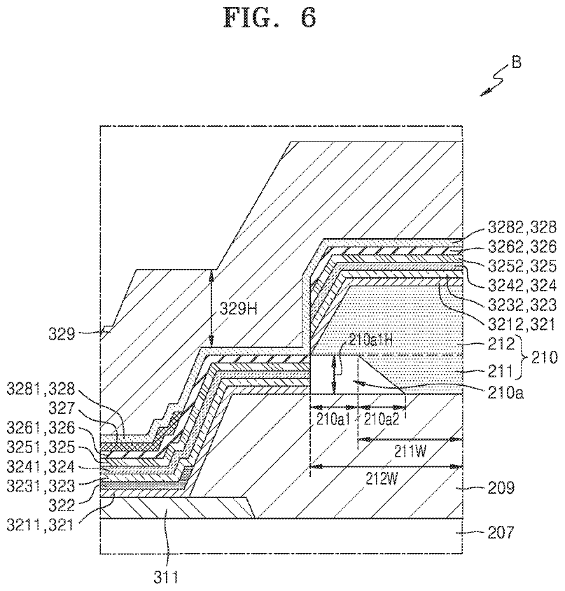

FIG. 6 is a schematic cross-sectional view of a portion of a display apparatus according to an embodiment. In the case of the display apparatus according to an embodiment, the height 210a1H of the 1^{st}-1^{st} portion 210a1 having the constant height of the first undercut 210a is shown to be the same as the height from the upper surface of the pixel-defining layer 209 to the upper surface of the 2^{nd}-1^{st} common layer. For example, the height 210a1H of the first portion 211 of the separator 210 is shown to be the same as the height from the upper surface of the pixel-defining layer 209 to the upper surface of the 2^{nd}-1^{st} common layer. The third common layer 328 may not be separated by the first undercut 210a of the separator 210. In other words, the 3^{rd}-1^{st} common layer 3281 and the 3^{rd}-2^{nd} common layer 3282 of the third common layer 328 may be connected to each other without being apart from each other. Accordingly, the third common layer 328 may be integrated with the first pixel PX1, the second pixel PX2, and the third pixel PX3.

However, even in this case, the second charge generating layer included in the 2^{nd}-2^{nd} common layer on the separator 210 is apart from the first charge generating layer included in the 2^{nd}-1^{st} common layer on the first pixel electrode 311. As a result, the movement of electrons or holes generated in the portion of the first charge generating layer above the first pixel electrode 311 to the second pixel PX2 may be effectively prevented or minimized, so that a display apparatus displaying a high-quality image may be implemented. In case that the opposite electrode 329 is formed, a defect such as disconnection of the opposite electrode 329 may be effectively prevented by reducing a step difference caused by the separator 210 under or below the opposite electrode 329.

So far, the structure disposed over the first pixel electrode 311 has been described, but the disclosure is not limited thereto. The description as described above with respect to the structure disposed over the first pixel electrode 311 may be applied to a structure disposed over the second pixel electrode 312.

For example, as shown in FIG. 7, which is a schematic cross-sectional view showing an enlarged portion C of FIG. 4, the first common layer 321 may further include a 1^{st}-3^{rd} common layer 3213 disposed over the second pixel electrode 312. The 1^{st}-3^{rd} common layer 3213 may be on a portion of the pixel-defining layer 209 as shown in FIG. 7 as well as on the second pixel electrode 312. Because the separator 210 has the second undercut 210a′ similar to the first undercut 210a at a lower portion of the separator 210 in a direction to a center of the second pixel electrode 312, the 1^{st}-2^{nd} common layer 3212 disposed over the separator 210 is apart from the 1^{st}-3^{rd} common layer 3213 disposed over the second pixel electrode 312. The 1^{st}-3^{rd} common layer 3213 disposed over the second pixel electrode 312 may be integrally formed as a single body with the 1^{st}-1^{st} common layer 3211 disposed over the first pixel electrode 311. This is because the separator 210 is located as shown in FIGS. 2A, 2B, 3A, 3B, 3C, and 3D, so that a portion of the first common layer 321 disposed over the first pixel electrode 311, a portion of the first common layer 321 disposed over the second pixel electrode 312, and a portion of the first common layer 321 disposed over the third pixel electrode 313 may bypass the separator 210 and be connected to each other to be integrally formed as a single body.

A 2^{nd}-1^{st} emission layer 322′ is on the 1^{st}-3^{rd} common layer 3213. The 2^{nd}-1^{st} emission layer 322′ may emit, for example, green light.

A second common layer may further include a 2^{nd}-3^{rd} common layer apart from the 2^{nd}-2^{nd} common layer by the second undercut 210a′ of the separator 210 and disposed on the 2^{nd}-1^{st} emission layer 322′. As described above, because the second common layer may have a multilayer structure, FIG. 7 shows that the 2^{nd}-3^{rd} common layer may include the electron transport layer 3233, the electron generating layer 3243, the hole generating layer 3253, and the hole transport layer 3263. The 2^{nd}-3^{rd} common layer may further include an electron injection layer interposed between the electron transport layer 3233 and the electron generation layer 3243, and may further include a hole injection layer interposed between the hole generating layer 3253 and the hole transport layer 3263.

The 2^{nd}-3^{rd} common layer may also be on a portion of the 1^{st}-3^{rd} common layer 3213 outside the 2^{nd}-1^{st} emission layer 322′ as shown in FIG. 7 as well as on the 2^{nd}-1^{st} emission layer 322′. The 2^{nd}-3^{rd} common layer may include a same material or a similar material as that of the 2^{nd}-2^{nd} common layer and may have a same layer structure as that of the 2^{nd}-2^{nd} common layer. The 2^{nd}-3^{rd} common layer on the second pixel electrode 312 may be integrated with the 2^{nd}-1^{st} common layer on the first pixel electrode 311. This is because the separator 210 is located as shown in FIGS. 2A, 2B, 3A, 3B, 3C, and 3D, so that a portion of the second common layer on the first pixel electrode 311, a portion of the second common layer on the second pixel electrode 312, and a portion of the second common layer on the third pixel electrode 313 may bypass the separator 210 and be connected to each other to be integrally formed as a single body.

A 2^{nd}-2^{nd} emission layer 327′ is on the 2^{nd}-3^{rd} common layer. The 2^{nd}-2^{nd} emission layer 327′ may emit light belonging to the same wavelength band as that of the 2^{nd}-1^{st} emission layer 322′. For example, the 2^{nd}-2^{nd} emission layer 327′ and the 2^{nd}-1^{st} emission layer 322′ may emit green light.

The third common layer 328 may further include a 3^{rd}-3^{rd} common layer 3283 apart from the 3^{rd}-2^{nd} common layer 3282 by the second undercut 210a′. The 3^{rd}-3^{rd} common layer 3283 may be interposed between the 2^{nd}-2^{nd} emission layer 327′ and the opposite electrode 329. The 3^{rd}-3^{rd} common layer 3283 may be disposed over not only the 2^{nd}-2^{nd} emission layer 327′ but also a portion of the 2^{nd}-3^{rd} common layer as shown in FIG. 7. Here, the portion of the 2^{nd}-3^{rd} common layer is outside the 2^{nd}-2^{nd} emission layer 327′. The 3^{rd}-3^{rd} common layer 3283 may include a same material or a similar material as that of the 3^{rd}-2^{nd} common layer 3282 and may have a same layer structure as that of the 3^{rd}-2^{nd} common layer 3282. The 3^{rd}-3^{rd} common layer 3283 disposed over the second pixel electrode 312 may be integrally formed as a single body with the 3^{rd}-1^{st} common layer 3281 disposed over the first pixel electrode 311. This is because the separator 210 is located as shown in FIGS. 2A, 2B, 3A, 3B, 3C, and 3D, so that a portion of the third common layer 328 disposed on the first pixel electrode 311, a portion of the third common layer 328 disposed on the second pixel electrode 312, and a portion of the third common layer 328 disposed on the third pixel electrode 313 may bypass the separator 210 and be connected to each other to be integrally formed as a single body.

In the case of the display apparatus according to an embodiment, as described above, the 2^{nd}-3^{rd} common layer on the second pixel electrode 312 may include the electron generating layer 3243 and the hole generating layer 3253, as a third charge generating layer. The 2^{nd}-1^{st} emission layer 322′ is below the third charge generating layer, and the 2^{nd}-2^{nd} emission layer 327′ is disposed over the third charge generating layer. Accordingly, because light is emitted not only by the 2^{nd}-1^{st} emission layer 322′ but also by the 2^{nd}-2^{nd} emission layer 327′ on the second pixel electrode 312, the second pixel PX2 may emit light of high luminance.

In order to emit light by the 2^{nd}-1^{st} emission layer 322′ and the 2^{nd}-2^{nd} emission layer 327′, as described above, the electron generating layer 3243 and the hole generating layer 3253, which form the third charge generating layer, need to be interposed between the 2^{nd}-1^{st} emission layer 322′ and the 2^{nd}-2^{nd} emission layer 327′. The electron generating layer 3243 generates electrons and supplies them to the 2^{nd}-1^{st} emission layer 322′ so that light is emitted from the 2^{nd}-1^{st} emission layer 322′ receiving holes from the second pixel electrode 312, and the hole generating layer 3253 generates holes and supplies them to the 2^{nd}-2^{nd} emission layer 327′ so that light is emitted from the 2^{nd}-2^{nd} emission layer 327′ receiving electrons from the opposite electrode 329.

Because the separator 210 has the second undercut 210a′ as described above, the second charge generating layer included in the 2^{nd}-2^{nd} common layer on the separator 210 is apart from the third charge generating layer included in the 2^{nd}-3^{rd} common layer on the second pixel electrode 312. As a result, in order for electrons or holes generated in the portion of the third charge generating layer above the second pixel electrode 312 to move to the first pixel PX1, the separator 210 must be bypassed. Accordingly, by rapidly increasing the moving path, it is possible to effectively prevent or minimize the movement of electrons or holes generated in the portion of the third charge generating layer above the second pixel electrode 312 to the first pixel PX1, and it is possible to implement a display apparatus that displays a high-quality image.

The above description of the first undercut 210a may also be applied to the second undercut 210a′. As shown in FIG. 7, the second undercut 210a′ may include a 2^{nd}-1^{st} portion 210a1′ having a constant height, and a 2^{nd}-2^{nd} portion 210a2′ connected to the 2^{nd}-1^{st} portion 210a1′ and having a decreasing height. The 2^{nd}-1^{st} portion 210a1′ is relatively closer to the center of the second pixel electrode 312 than the 2^{nd}-2^{nd} portion 210a2′.

The second undercut 210a′ separates the 1^{st}-3^{rd} common layer 3213 and the 1^{st}-2^{nd} common layer 3212, and accordingly, the 1^{st}-3^{rd} common layer 3213 does not overlap the second undercut 210a′ in a plan view. Because the second undercut 210a′ is to prevent electrons or holes generated in the portion of the third charge generating layer above the second pixel electrode 312 from moving to the first pixel PX1, if necessary, the second undercut 210a′ may encircle the second pixel electrode 312. Because the second undercut 210a′ is included in the separator 210, in order for the second undercut 210a′ to go around the second pixel electrode 312, the separator 210 may have a portion that goes around the second pixel electrode 312. For reference, FIG. 2A shows that the separator 210 does not have a portion that encircles the second pixel electrode 312, but the separators 210 are located between the second pixel electrode 312 and pixel electrodes adjacent thereto.

The second undercut 210a′ separates the 2^{nd}-3^{rd} common layer including the third charge generating layer and the 2^{nd}-2^{nd} common layer including the second charge generating layer. Accordingly, the height 210a1H of the 2^{nd}-1^{st} portion 210a1′ having a constant height of the second undercut 210a′ needs to be greater than or equal to a height from the upper surface of the pixel-defining layer 209 to the upper surface of the 2^{nd}-3^{rd} common layer. For example, the height 210a1H of the first portion 211 of the separator 210 needs to be greater than or equal to the height from the upper surface of the pixel-defining layer 209 to the upper surface of the 2^{nd}-3^{rd} common layer.

The opposite electrode 329 may be integrally formed as a single body over pixels. It is necessary to prevent the portion of the opposite electrode 329 above the second pixel electrode 312 from being apart from the portion of the opposite electrode 329 above the first pixel electrode 311 by the second undercut 210a′. Accordingly, in order to ensure that the opposite electrode 329 may be integrally formed as a single body over the pixels, the thickness 329H of the opposite electrode 329 may be greater than the distance between a portion of the lower surface of the separator 210 that is not in contact with the pixel-defining layer 209 and the upper surface of the pixel-defining layer 209. For example, the thickness 329H of the opposite electrode 329 may be greater than the height 210a1H of the second undercut 210a′. For example, the thickness 329H of the opposite electrode 329 may be greater than the height 210a1H of the first portion 211 of the separator 210.

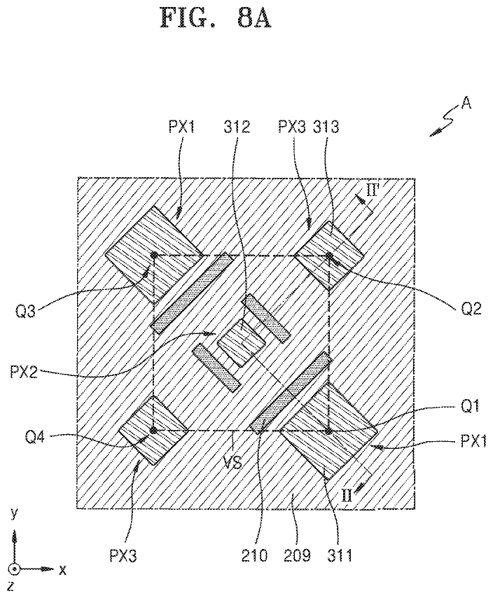

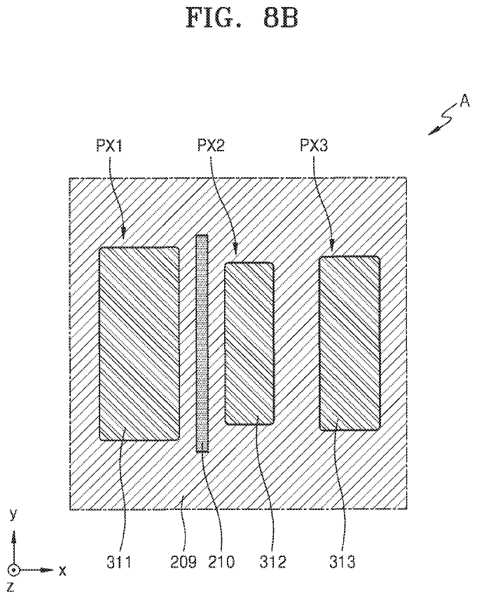

So far, the case in which the display apparatus may include the spacer 220 has been described, but the disclosure is not limited thereto. For example, as shown in FIG. 8A, which is a schematic plan view illustrating a portion of a display apparatus according to an embodiment, the first pixel PX1, the second pixel PX2, and the third pixel PX3 may be arranged in a PENTILE™ manner and the spacer 220 may not exist. The separator 210 may be located to correspond between the first pixel PX1 and the second pixel PX2 as shown in FIG. 8A. For example, the separator 210 may be located to correspond between the first pixel electrode 311 and the second pixel electrode 312. However, the display apparatus according to an embodiment may include the separators 210. For example, as shown in FIG. 8A, the separator 210 may also be located between the second pixel PX2 and the third pixel PX3.

The disclosure is not limited to arranging the first pixel PX1, the second pixel PX2, and the third pixel PX3 in a PENTILE™ manner. For example, as shown in FIG. 8B, which is a schematic plan view illustrating a portion of a display apparatus according to an embodiment, the first pixel PX1, the second pixel PX2, and the third pixel PX3 may be arranged in a stripe manner. For example, the first pixel PX1, the second pixel PX2, and the third pixel PX3 may be sequentially arranged in the x-axis direction. As can be seen in FIG. 8B, the spacer 220 may not exist. By way of example, the pixels may be arranged in a mosaic manner.

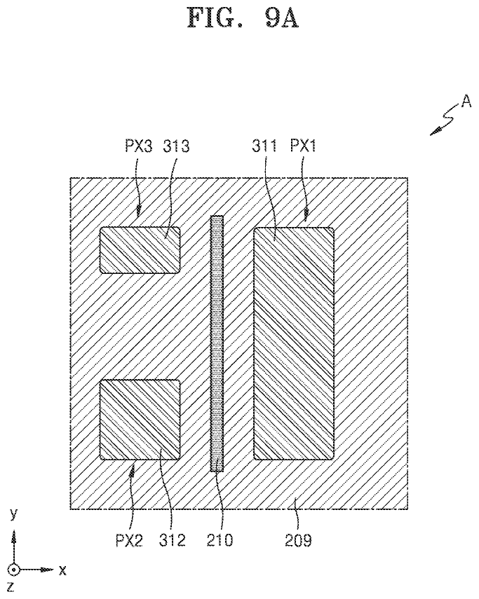

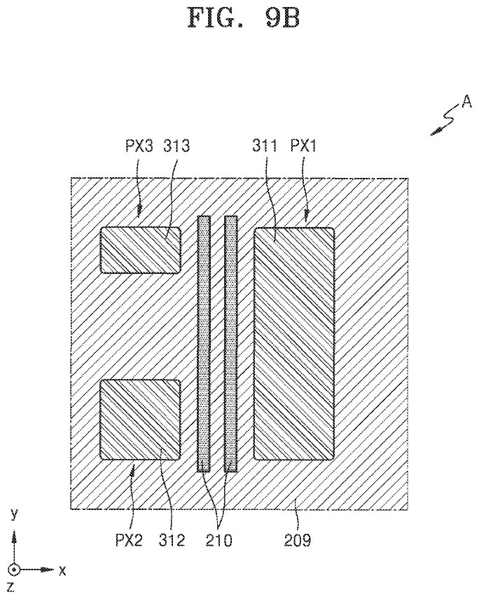

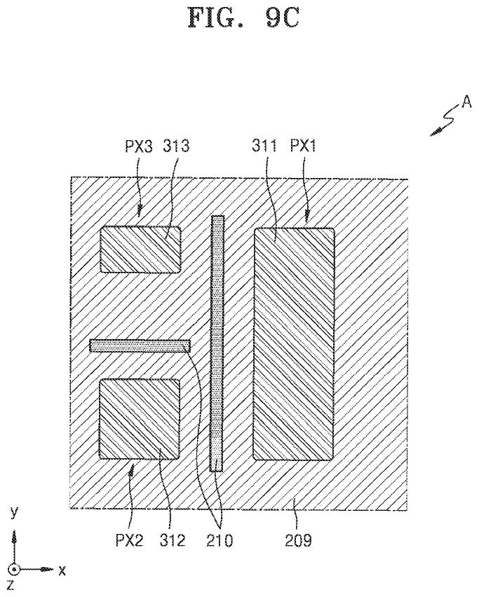

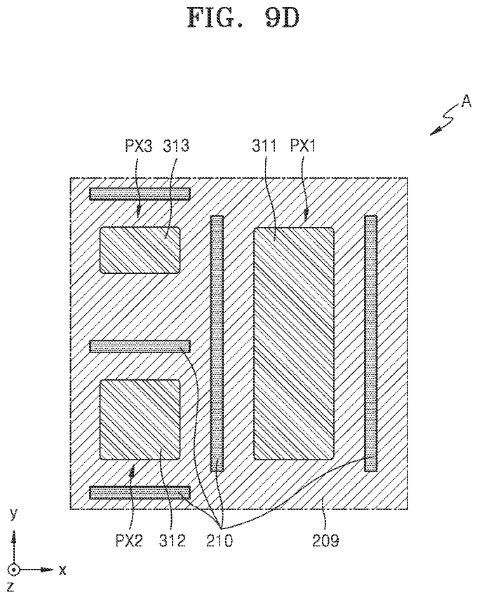

As shown in FIGS. 9A to 9D, which are schematic plan views illustrating a portion of a display apparatus according to an embodiment, the first pixel PX1, the second pixel PX2, and the third pixel PX3 may be arranged in a S-stripe manner. As shown in FIG. 9A, for example, the separator 210 may be located to correspond between the second pixel PX2 emitting green light, the third pixel PX3 emitting red light, and the first pixel PX1 emitting blue light. The spacer 220 may not exist. As shown in FIG. 9B, two separators 210 may be located between the second pixel PX2 and the third pixel PX3 and the first pixel PX1.

As shown in FIG. 9C, the separator 210 may be located to correspond between the second pixel PX2 and the third pixel PX3 and the first pixel PX1, and may also be located between the second pixel PX2 and the third pixel PX3. Because the separator 210 is located between the third pixel PX3 and the second pixel PX2 (located in the −y direction), the separator 210 may not be located between the third pixel PX3 and the second pixel PX2 (not shown and located in the +y direction), and may also not be located between the second pixel PX2 and the third pixel PX3 (not shown and located in the −y direction). The spacer 220 may not exist. As shown in FIG. 9D, the separators 210 may be located on both sides (in the +x and −x directions) of the first pixel PX1, or may be located between the second pixels PX2 and the third pixels PX3 arranged along the y-axis direction.

However, the disclosure is not limited thereto. For example, the separator 210 may encircle the first pixel PX1 in a plan view. For example, the separator 210 may encircle the first pixel electrode 311 in a plan view.

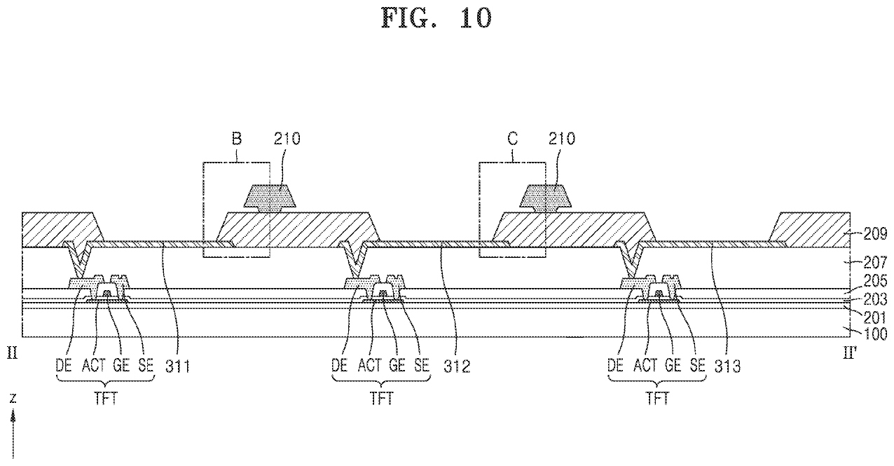

FIG. 10 is a schematic cross-sectional view of the display apparatus of FIG. 8A taken along line II-II′ in FIG. 8A. FIG. 5 may be understood as an enlarged schematic cross-sectional view of portion B of FIG. 10. As shown in FIG. 10, the case in which the spacer 220 does not exist is also included in the scope of the disclosure.

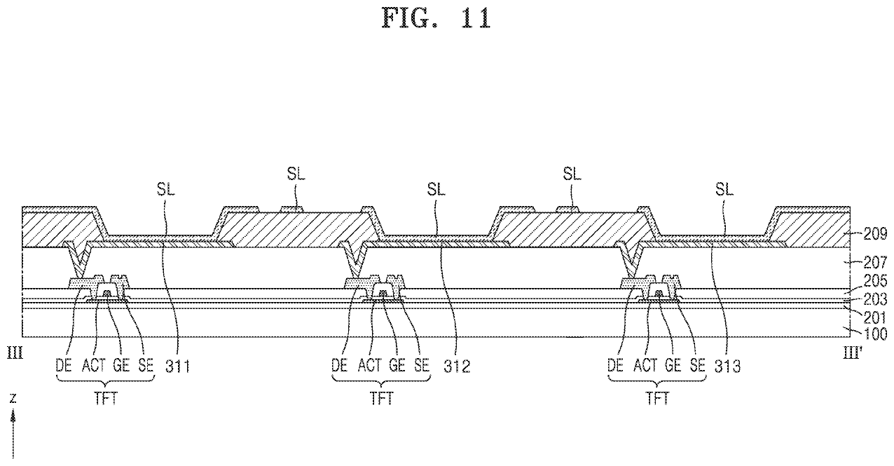

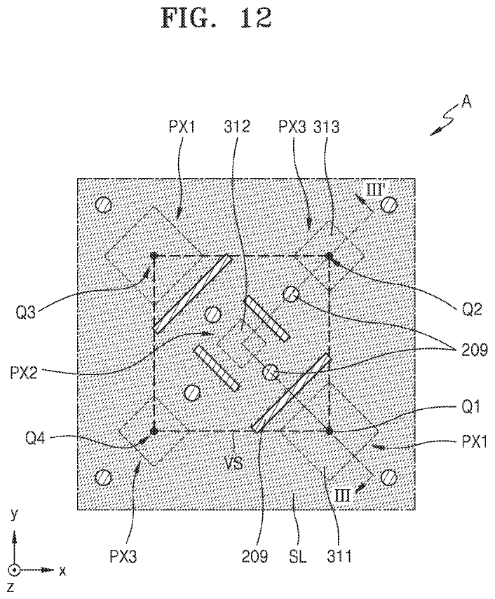

FIGS. 11 to 13 are views for explaining a method of manufacturing a display apparatus according to an embodiment. FIG. 11 is a schematic cross-sectional view of the display apparatus of FIG. 12 taken along line III-III′ in FIG. 12.

As shown in FIGS. 11 and 12, after forming the pixel-defining layer 209 covering edges of the first pixel electrode 311, the second pixel electrode 312, and the third pixel electrode 313, a sacrificial layer SL is formed. The sacrificial layer SL is disposed over an exposed portion of the third pixel electrode 313, an exposed portion of the first pixel electrode 311, an exposed portion of the second pixel electrode 312, and the pixel-defining layer 209. A portion of an upper surface of the pixel-defining layer 209 corresponding to a portion of a lower surface of the separator 210 to be formed later that comes into contact with the pixel-defining layer 209 and a portion of an upper surface of the pixel-defining layer 209 corresponding to a lower surface of the spacer 220 are not covered by the sacrificial layer SL.

To this end, a sacrificial layer corresponding to the entire surface of the substrate 100 may be formed and patterned to form the sacrificial layer SL. For example, the sacrificial layer SL may be formed by forming an IGZO layer, an ITO layer, or a ZTO layer on the entire surface of the substrate 100 by sputtering and patterning the IGZO layer, the ITO layer, or the ZTO layer using a photoresist or the like within the spirit and the scope of the disclosure. Because the sacrificial layer SL is formed through this patterning, in the vicinity of each of openings exposing the pixel-defining layer 209 of the sacrificial layer SL, the sacrificial layer SL may have a portion of which the thickness decreases as it approaches the opening.

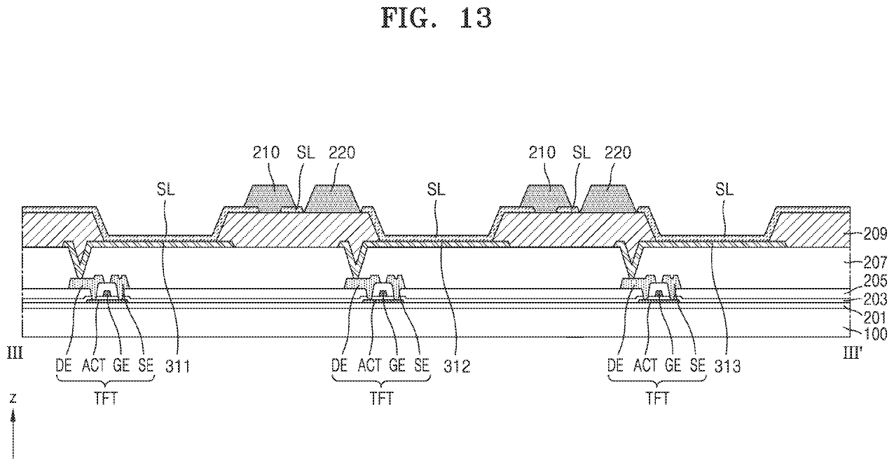

As shown in FIG. 13, the separator 210 is formed on the pixel-defining layer 209 such that the separator 210 covers at least a part of a portion of the sacrificial layer SL. The portion of the sacrificial layer SL is on the pixel-defining layer 209. The spacer 220 located within an opening of the sacrificial layer SL and having a lower surface may be simultaneously formed. Here, an entire area of the lower surface of the spacer 220 is in contact with the upper surface of the pixel-defining layer 209. The separator 210 and the spacer 220 may be simultaneously formed of a same material or a similar material by forming an insulating layer covering the sacrificial layer SL and patterning the insulating layer.

Thereafter, by removing the sacrificial layer SL, the separator 210 having the first undercut 210a and the separator 210 having the second undercut 210a′ may be formed. A wet etching method may be used to remove the sacrificial layer SL. Only the sacrificial layer SL is selectively removed, and the pixel-defining layer 209, the separator 210, and the spacer 220 may be hardly damaged. This is because an etch ratio of the sacrificial layer SL is greater than that of the pixel-defining layer 209, the separator 210, and the spacer 220.

As described above, in the vicinity of each of openings exposing the pixel-defining layer 209 of the sacrificial layer SL, the sacrificial layer SL has a portion wherein the thickness decreases as it approaches the opening, and thus, the first undercut 210a and the second undercut 210a′ have shapes corresponding to that of the sacrificial layer SL. As shown in FIG. 5, the first undercut 210a may include the 1^{st}-1^{st} portion 210a1 having a constant height, and the 1^{st}-2^{nd} portion 210a2 connected to the 1^{st}-1^{st} portion 210a1 and having a decreasing height. The 1^{st}-1^{st} portion 210a1 is relatively closer to the center of the first pixel electrode 311 than the 1^{st}-2^{nd} portion 210a2. As shown in FIG. 7, the second undercut 210a′ may include the 2^{nd}-1^{st} portion 210a1′ having a constant height, and the 2^{nd}-2^{nd} portion 210a2′ connected to the 2^{nd}-1^{st} portion 210a1′ and having a decreasing height. The 2^{nd}-1^{st} portion 210a1′ is relatively closer to the center of the second pixel electrode 312 than the 2^{nd}-2^{nd} portion 210a2′.

Thereafter, an organic light-emitting display device may be manufactured, using a deposition method, by forming the first common layer 321 including the 1^{st}-1^{st} common layer 3211, the 1^{st}-2^{nd} common layer 3212, and the 1^{st}-3^{rd} common layer 3213, by forming the 1^{st}-1^{st} emission layer 322 and the 2^{nd}-1^{st} emission layer 322′, by forming a second common layer including a first charge generating layer, a second charge generating layer, and a third charge generating layer, by forming the 1^{st}-2^{nd} emission layer 327 and the 2^{nd}-2^{nd} emission layer 327′, by forming the third common layer 328 including the 3^{rd}-1^{st} common layer 3281, the 3^{rd}-2^{nd} common layer 3282, and the 3^{rd}-3^{rd} common layer 3283, and by forming the opposite electrode 329, as described above. The opposite electrode 329 is formed to have a thickness greater than that of the sacrificial layer SL, and as a result, as described above, the opposite electrode 329 may be formed to have a thickness greater than the height of the first undercut 210a of the separator 210.

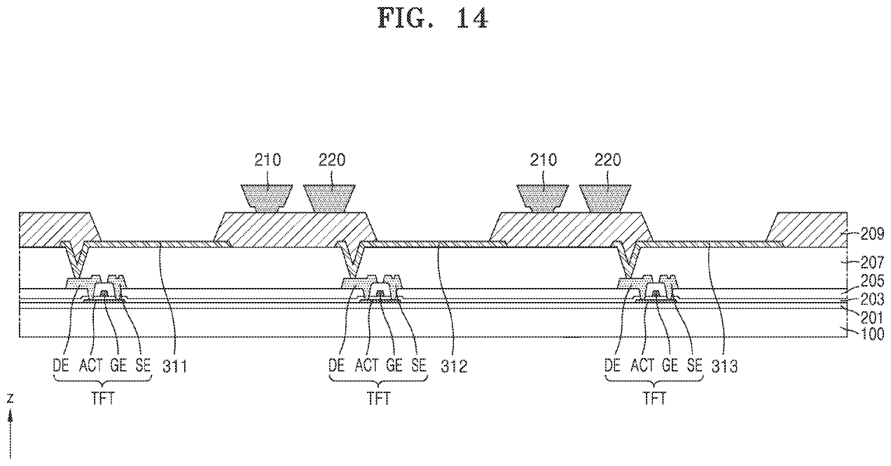

FIG. 14 is a schematic cross-sectional view of a portion of a display apparatus according to an embodiment. As shown in FIG. 14, an area of an upper surface of the separator 210 may be greater than an area of a lower surface of the separator 210. For example, by making a second width 212W of the second portion 212 of the separator 210 increase as it goes up (in the +z direction), for example, by making a part of the separator 210 above the first undercut 210a have a cross-sectional area in a plane perpendicular to an upward direction such that the cross-sectional area increases as the plane goes upward (in the +z direction), the separator 210 having the first undercut 210a and the separator 210 having the second undercut 210a′ may have an inverted taper shape. Through this, separation of layers by the separator 210 may be made more reliably.

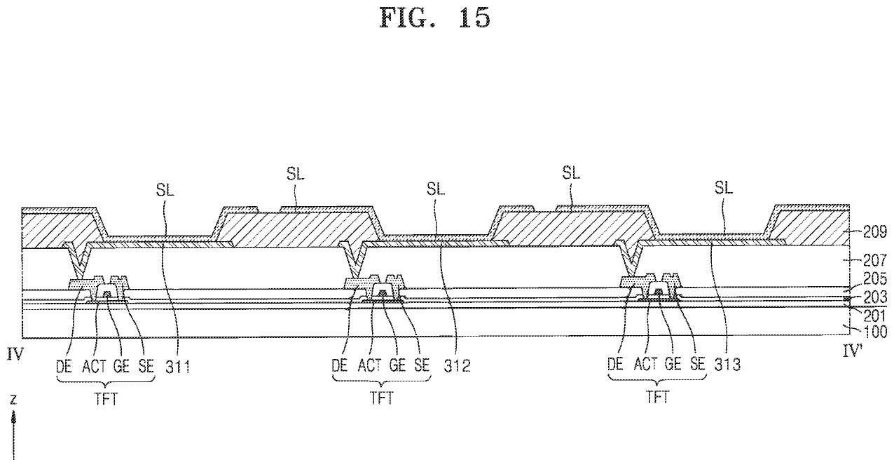

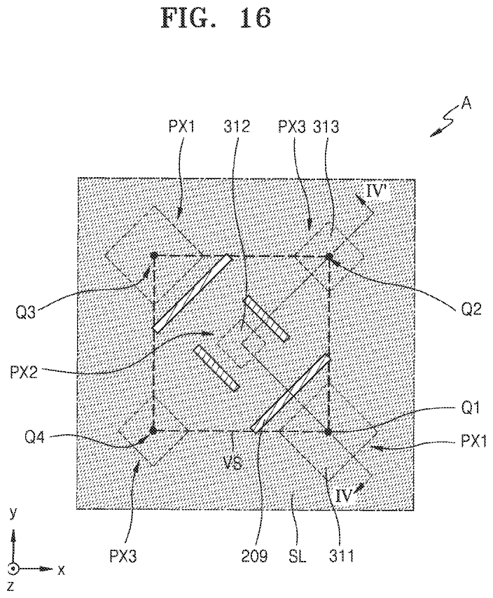

FIGS. 15 to 17 are views for explaining a method of manufacturing a display apparatus according to an embodiment. FIG. 15 is a schematic cross-sectional view of the display apparatus of FIG. 16 taken along line IV-IV′ in FIG. 16.

As shown in FIGS. 15 and 16, after forming the pixel-defining layer 209 covering edges of the first pixel electrode 311, the second pixel electrode 312, and the third pixel electrode 313, the sacrificial layer SL is formed. The sacrificial layer SL is disposed over an exposed portion of the first pixel electrode 311, an exposed portion of the second pixel electrode 312, an exposed portion of the third pixel electrode 313, and the pixel-defining layer 209. A portion of an upper surface of the pixel-defining layer 209 corresponding to a portion of a lower surface of the separator 210 to be formed later that comes into contact with the pixel-defining layer 209 is not covered by the sacrificial layer SL.

To this end, a sacrificial layer corresponding to the entire surface of the substrate 100 may be formed and patterned to form the sacrificial layer SL. For example, the sacrificial layer SL may be formed by forming an IGZO layer, an ITO layer, or a ZTO layer on the entire surface of the substrate 100 by sputtering and patterning the IGZO layer, the ITO layer, or the ZTO layer using a photoresist or the like within the spirit and the scope of the disclosure. Because the sacrificial layer SL is formed through this patterning, in the vicinity of each of openings exposing the pixel-defining layer 209 of the sacrificial layer SL, the sacrificial layer SL may have a portion wherein the thickness decreases as it approaches the opening.

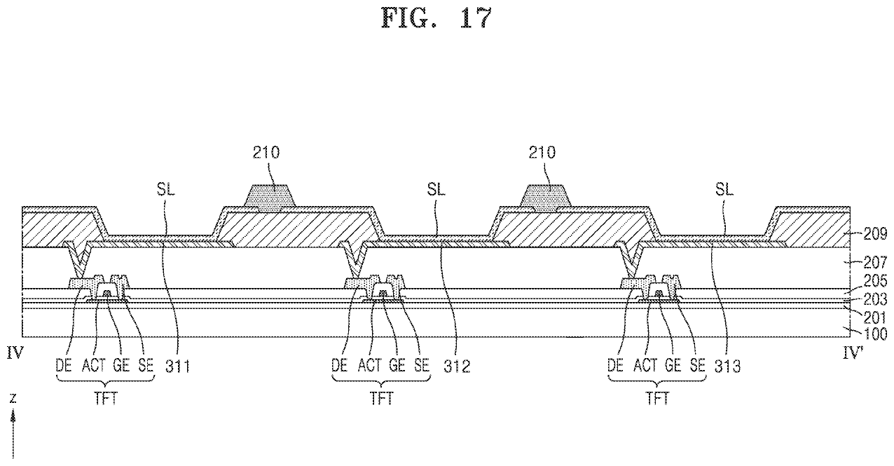

As shown in FIG. 17, the separator 210 is formed on the pixel-defining layer 209 such that the separator 210 covers at least a part of a portion of the sacrificial layer SL. The portion of the sacrificial layer SL is on the pixel-defining layer 209. The separator 210 may be formed by forming an insulating layer covering the sacrificial layer SL and patterning the insulating layer.

Thereafter, by removing the sacrificial layer SL, the separator 210 having the first undercut 210a and the separator 210 having the second undercut 210a′ may be formed. A wet etching method may be used to remove the sacrificial layer SL. Only the sacrificial layer SL is selectively removed, and the pixel-defining layer 209 and the separator 210 may be hardly damaged. This is because an etch ratio of the sacrificial layer SL is greater than that of the pixel-defining layer 209 and the spacer 220.

As described above, in the vicinity of each of openings exposing the pixel-defining layer 209 of the sacrificial layer SL, the sacrificial layer SL has a portion wherein the thickness decreases as it approaches the opening, and thus, the first undercut 210a and the second undercut 210a′ have shapes corresponding to that of the sacrificial layer SL. As shown in FIG. 5, the first undercut 210a may include the 1^{st}-1^{st} portion 210a1 having a constant height, and the 1^{st}-2^{nd} portion 210a2 connected to the 1^{st}-1^{st} portion 210a1 and having a decreasing height. The 1^{st}-1^{st} portion 210a1 is relatively closer to the center of the first pixel electrode 311 than the 1^{st}-2^{nd} portion 210a2. As shown in FIG. 7, the second undercut 210a′ may include the 2^{nd}-1^{st} portion 210a1′ having a constant height, and the 2^{nd}-2^{nd} portion 210a2′ connected to the 2^{nd}-1^{st} portion 210a1′ and having a decreasing height. The 2^{nd}-1^{st} portion 210a1′ is relatively closer to the center of the second pixel electrode 312 than the 2^{nd}-2^{nd} portion 210a2′.

Thereafter, an organic light-emitting display device may be manufactured, using a deposition method, by forming the first common layer 321 including the 1^{st}-1^{st} common layer 3211, the 1^{st}-2^{nd} common layer 3212, and the 1^{st}-3^{rd} common layer 3213, by forming the 1^{st}-1^{st} emission layer 322 and the 2^{nd}-1^{st} emission layer 322′, by forming a second common layer including a first charge generating layer, a second charge generating layer, and a third charge generating layer, by forming the 1^{st}-2^{nd} emission layer 327 and the 2 emission layer 327′, by forming the third common layer 328 including the 3^{rd}-1^{st} common layer 3281, the 3^{rd}-2^{nd} common layer 3282, and the 3^{rd}-3^{rd} common layer 3283, and by forming the opposite electrode 329, as described above. The opposite electrode 329 is formed to have a thickness greater than that of the sacrificial layer SL, and as a result, as described above, the opposite electrode 329 may be formed to have a thickness greater than the height of the first undercut 210a of the separator 210.

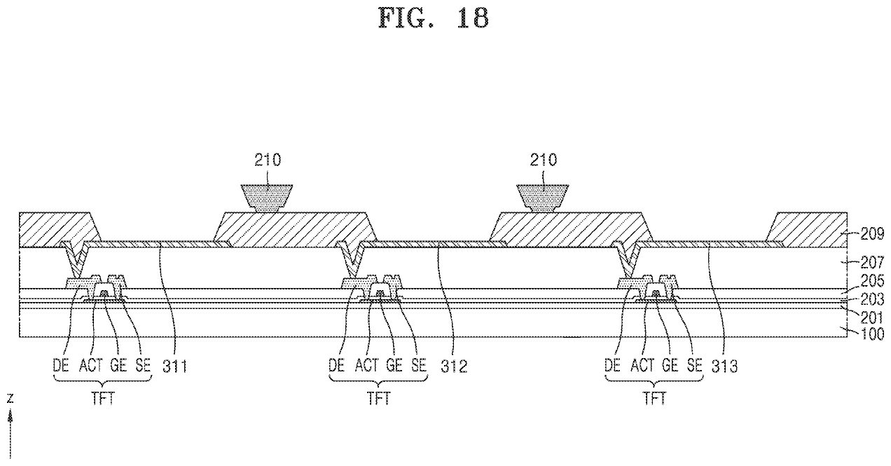

FIG. 18 is a schematic cross-sectional view of a portion of a display apparatus according to an embodiment. As shown in FIG. 18, the case in which the spacer 220 does not exist is also included in the scope of the disclosure. An area of an upper surface of the separator 210 may be greater than an area of a lower surface of the separator 210. For example, by making the second width 212W of the second portion 212 of the separator 210 increase as it goes up (in the +z direction), for example, by making the part of the separator 210 above the first undercut 210a have a cross-sectional area in the plane perpendicular to the upward direction such that the cross-sectional area increases as the plane goes upward (in the +z direction), the separator 210 having the first undercut 210a and the separator 210 having the second undercut 210a′ may have an inverted taper shape. Through this, separation of layers by the separator 210 may be made more reliably.

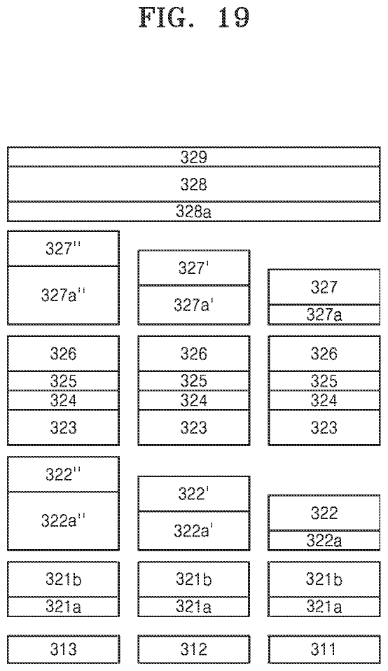

FIG. 19 is a conceptual diagram of a portion of a display apparatus according to an embodiment, and schematically illustrates a stacked structure in each of the first pixel PX1, the second pixel PX2, and the third pixel PX3. As shown in FIG. 19, the first pixel electrode 311, the second pixel electrode 312, and the third pixel electrode 313 are apart from each other. The first pixel electrode 311 may be a pixel electrode of a first pixel PX1 emitting blue light, the second pixel electrode 312 may be a pixel electrode of a second pixel PX2 emitting green light, and the third pixel electrode 313 may be a pixel electrode of the third pixel PX3 emitting red light.

A hole injection layer 321a and a hole transport layer 321b may be disposed over the first pixel electrode 311, the second pixel electrode 312, and the third pixel electrode 313. The 1^{st}-1^{st} emission layer 322 corresponding to the first pixel electrode 311, the 2^{nd}-1^{st} emission layer 322′ corresponding to the second pixel electrode 312, and a 3^{rd}-1^{st} emission layer 322″ corresponding to the third pixel electrode 313 may be disposed over the hole transport layer 321b. A blue auxiliary layer 322a may be interposed between the 1^{st}-1^{st} emission layer 322 that emits blue light and the hole transport layer 321b, an auxiliary hole transport layer 322a′ may be interposed between the 2^{nd}-1^{st} emission layer 322′ that emits green light and the hole transport layer 321b, and an auxiliary hole transport layer 322a″ may be interposed between the 3^{rd}-1^{st} emission layer 322″ that emits red light and the hole transport layer 321b.

The blue auxiliary layer 322a may improve the light generation efficiency of the 1^{st}-1^{st} emission layer 322 by adjusting the hole charge balance. The auxiliary hole transport layer 322a′ has a preset thickness determined according to a resonance period of light emitted from the 2^{nd}-1^{st} emission layer 322′, and may improve the color purity of light emitted from the 2^{nd}-1^{st} emission layer 322′ or improve the luminous efficiency of the second pixel PX2. Similarly, the auxiliary hole transport layer 322a″ has a preset thickness determined according to a resonance period of light emitted from the 3^{rd}-1^{st} emission layer 322″, and may improve the color purity of light emitted from the 3^{rd}-1^{st} emission layer 322″ or improve the luminous efficiency of the third pixel PX3.

FIG. 19 illustrates the hole injection layer 321a as being apart from each of the first pixel electrode 311, the second pixel electrode 312, and the third pixel electrode 313. However, as described above, a portion on the first pixel electrode 311, a portion on the second pixel electrode 312, and a portion on the third pixel electrode 313 of the hole injection layer 321a may be connected to each other bypassing the separator 210. This is the same in the case of the hole transport layer 321b.

The electron transport layer 323, the electron generating layer 324, the hole generating layer 325, and the hole transporting layer 326 are sequentially disposed on the 1^{st}-1^{st} emission layer 322, the 2^{nd}-1^{st} emission layer 322′, and the 3^{rd}-1^{st} emission layer 322″. The 1^{st}-2^{nd} emission layer 327 corresponding to the first pixel electrode 311, the 2^{nd}-2^{nd} emission layer 327′ corresponding to the second pixel electrode 312, and a 3^{rd}-2^{nd} emission layer 327″ corresponding to the third pixel electrode 313 may be disposed over the hole transport layer 326. A blue auxiliary layer 327a may be interposed between the 1^{st}-2^{nd} emission layer 327 that emits blue light and the hole transport layer 326, an auxiliary hole transport layer 327a′ may be interposed between the 2^{nd}-2^{nd} emission layer 327′ that emits green light and the hole transport layer 326, and an auxiliary hole transport layer 327a″ may be interposed between the 3^{rd}-2^{nd} emission layer 327″ that emits red light and the hole transport layer 326. The description of the blue auxiliary layer 322a, the auxiliary hole transport layer 322a′, and the auxiliary hole transport layer 322a″ described above may be equally applied to the blue auxiliary layer 327a, the auxiliary hole transport layer 327a′, and the auxiliary hole transport layer 327a″.

FIG. 19 illustrates the electron transport layer 323 as being apart from each of the first pixel electrode 311, the second pixel electrode 312, and the third pixel electrode 313. However, as described above, a portion on the first pixel electrode 311, a portion on the second pixel electrode 312, and a portion on the third pixel electrode 313 of the electron transport layer 323 may be connected to each other bypassing the separator 210. This is the same in the case of the electron generating layer 324, the hole generating layer 325, and the hole transporting layer 326.

An electron transport layer 328, which may be referred to as the above-described third common layer 328, is disposed over the 1^{st}-2^{nd} emission layer 327, the 2^{nd}-2^{nd} emission layer 327′, and the 3^{rd}-2^{nd} emission layer 327″. If necessary, a buffer layer 328a may be interposed between the 1^{st}-2^{nd} emission layer 327, the 2^{nd}-2^{nd} emission layer 327′, and the 3^{rd}-2^{nd} emission layer 327″ and the electron transport layer 328. The opposite electrode 329 is disposed over the electron transport layer 328. In the buffer layer 328a, the electron transport layer 328 and/or the opposite electrode 329, a portion on the separator 210 and a portion outside the separator 210 may be connected to each other or may be apart from each other.

According to an embodiment as described above, a display apparatus that displays high-quality images and a method of manufacturing the same may be implemented. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display apparatus comprising:
a first pixel electrode;
a pixel-defining layer covering an edge of the first pixel electrode; and
a separator disposed on the pixel-defining layer, wherein only a portion of a lower surface of the separator contacts the pixel-defining layer.

2. The display apparatus of claim 1, further comprising:
a spacer disposed on the pixel-defining layer, wherein an entire lower surface of the spacer contacts the pixel-defining layer.

3. The display apparatus of claim 1, further comprising:
a first common layer overlapping the first pixel electrode, the pixel-defining layer, and the separator in a plan view, the first common layer being discontinuous between the pixel-defining layer and the separator.

4. The display apparatus of claim 3, wherein
the first common layer comprises:
a 1^{st}-1^{st} common layer overlapping the first pixel electrode in the plan view; and
a 1^{st}-2^{nd} common layer spaced apart from the 1^{st}-1^{st} common layer and overlapping the separator in the plan view.

5. The display apparatus of claim 4, further comprising:
a 1^{st}-1^{st} emission layer overlapping the 1^{st}-1^{st} common layer in the plan view;
a second common layer including a 2^{nd}-1^{st} common layer and a 2^{nd}-2^{nd} common layer spaced apart from the 2^{nd}-1^{st} common layer, wherein the 2^{nd}-1^{st} common layer overlaps the 1^{st}-1^{st} emission layer in the plan view, and the 2^{nd}-2^{nd} common layer overlaps the 1^{st}-2^{nd} common layer in the plan view;
a 1^{st}-2^{nd} emission layer overlapping the 2^{nd}-1^{st} common layer in the plan view; and
an opposite electrode overlapping the 1^{st}-2^{nd} emission layer and the separator in the plan view.

6. The display apparatus of claim 5, further comprising:
a third common layer including a 3^{rd}-1^{st} common layer and a 3^{rd}-2^{nd} common layer spaced apart from the 3^{rd}-1^{st} common layer, wherein the 3^{rd}-1^{st} common layer is disposed between the 1^{st}-2^{nd} emission layer and the opposite electrode, and the 3^{rd}-2^{nd} common layer is disposed between the 2^{nd}-2^{nd} common layer and the opposite electrode.

7. The display apparatus of claim 5, further comprising:
a third common layer integrally formed as a single body, the third common layer disposed between the 1^{st}-2^{nd} emission layer and the opposite electrode and disposed between the 2^{nd}-2^{nd} common layer and the opposite electrode.

8. The display apparatus of claim 5, wherein
the 2^{nd}-1^{st} common layer comprises a first charge generating layer, and the 2^{nd}-2^{nd} common layer comprises a second charge generating layer, and the second charge generating layer and the first charge generating layer include a same material.

9. The display apparatus of claim 4, wherein
the 1^{st}-1^{st} common layer does not overlap the separator in the plan view.

10. The display apparatus of claim 1, wherein
an area of an upper surface of the separator is greater than an area of the lower surface of the separator.

11. The display apparatus of claim 1, further comprising:
an opposite electrode overlapping the first pixel electrode, the pixel-defining layer, and the separator in a plan view, and having a thickness greater than a distance between a portion of the lower surface of the separator that does not contact the pixel-defining layer and an upper surface of the pixel-defining layer.

12. A display apparatus comprising:
a first pixel electrode;
a pixel-defining layer covering an edge of the first pixel electrode; and
a separator disposed on the pixel-defining layer, the separator having a first undercut at a lower portion of the separator in a direction to a center of the first pixel electrode.

13. The display apparatus of claim 12, further comprising:
a spacer disposed on the pixel-defining layer, wherein an entire lower surface of the spacer contacts the pixel-defining layer.

14. The display apparatus of claim 12, further comprising:
a first common layer overlapping the first pixel electrode, the pixel-defining layer, and the separator in a plan view, the first common layer being discontinuous between the pixel-defining layer and the separator.

15. The display apparatus of claim 14, wherein
the first common layer comprises:
a 1^{st}-1^{st} common layer overlapping the first pixel electrode in the plan view; and a 1^{st}-2^{nd} common layer spaced apart from the 1^{st}-1^{st} common layer and overlapping the separator in the plan view.

16. The display apparatus of claim 15, wherein
the 1^{st}-1^{st} common layer does not overlap the first undercut in the plan view.

17. The display apparatus of claim 15, further comprising:
a 1^{st}-1^{st} emission layer overlapping the 1^{st}-1^{st} common layer in the plan view;
a second common layer including a 2^{nd}-1^{st} common layer and a 2^{nd}-2^{nd} common layer spaced apart from the 2^{nd}-1^{st} common layer, wherein the 2^{nd}-1^{st} common layer overlaps the 1^{st}-1^{st} emission layer in the plan view, and the 2^{nd}-2^{nd} common layer overlaps the 1^{st}-2^{nd} common layer in the plan view;
a 1^{st}-2^{nd} emission layer overlapping the 2^{nd}-1^{st} common layer in the plan view; and
an opposite electrode overlapping the 1^{st}-2^{nd} emission layer and the separator in the plan view.

18. The display apparatus of claim 12, wherein
the first undercut comprises:
a 1^{st}-1^{st} portion having a constant height; and
a 1^{st}-2^{nd} portion connected to the 1^{st}-1^{st} portion and having a decreasing height.

19. The display apparatus of claim 18, wherein
the 1^{st}-1^{st} portion is closer to the center of the first pixel electrode than the 1^{st}-2^{nd} portion.

20. The display apparatus of claim 12, wherein
the separator encircles the first pixel electrode.

21. The display apparatus of claim 12, wherein
a part of the separator above the first undercut has a cross-sectional area in a plane perpendicular to an upward direction, the cross-sectional area increasing in the upward direction.

22. The display apparatus of claim 12, further comprising:
an opposite electrode overlapping the first pixel electrode, the pixel-defining layer, and the separator in a plan view, the opposite electrode having a thickness greater than a height of the first undercut.

23. The display apparatus of claim 12, further comprising:
a second pixel electrode spaced apart from the first pixel electrode, wherein
the pixel-defining layer covers an edge of the second pixel electrode, and
the separator is disposed between the first pixel electrode and the second pixel electrode and has a second undercut at the lower portion of the separator in a direction to a center of the second pixel electrode.

24. The display apparatus of claim 23, further comprising a first common layer including:
a 1^{st}-1^{st} common layer;
a 1^{st}-2^{nd} common layer spaced apart from the 1^{st-}1^{st} common layer; and
a 1^{st}-3^{rd} common layer spaced apart from the 1^{st}-2^{nd} common layer, the 1^{st}-1^{st} common layer overlapping the first pixel electrode in a plan view, the 1^{st}-2^{nd} common layer overlapping the separator in the plan view, the 1^{st}-3^{rd} common layer overlapping the second pixel electrode in the plan view.

25. The display apparatus of claim 24, wherein the 1^{st}-3^{rd} common layer does not overlap the second undercut in the plan view.

26. The display apparatus of claim 23, wherein
the second undercut comprises a 2^{nd}-1^{st} portion having a constant height, and a 2^{nd}-2^{nd} portion connected to the 2^{nd}-1^{st} portion and having a decreasing height.

27. The display apparatus of claim 26, wherein
the 2^{nd}-1^{st} portion is closer to the center of the second pixel electrode than the 2^{nd}-2^{nd} portion.

28. The display apparatus of claim 17, further comprising:
a third common layer including a 3^{rd}-1^{st} common layer and a 3^{rd}-2^{nd} common layer spaced apart from the 3^{rd}-1^{st} common layer, the 3^{rd}-1^{st} common layer disposed between the 1^{st}-2^{nd} emission layer and the opposite electrode, the 3^{rd}-2^{nd} common layer disposed between the 2^{nd}-2^{nd} common layer and the opposite electrode.

29. The display apparatus of claim 17, further comprising:
a third common layer integrally formed as a single body, the third common layer disposed between the 1^{st}-2^{nd} emission layer and the opposite electrode and disposed between the 2^{nd}-2^{nd} common layer and the opposite electrode.

30. The display apparatus of claim 17, wherein
the 2^{nd}-1^{st} common layer comprises a first charge generating layer, and the 2^{nd}-2^{nd} common layer comprises a second charge generating layer, and the second charge generating layer and the first charge generating layer include a same material.

31. A method of manufacturing a display apparatus, the method comprising:
forming a pixel-defining layer covering an edge of a first pixel electrode;
forming a sacrificial layer corresponding to the first pixel electrode, the sacrificial layer being disposed on an exposed portion of the first pixel electrode and the pixel-defining layer;
forming a separator on the pixel-defining layer, the separator covering at least a part of a portion of the sacrificial layer, the portion being disposed on the pixel-defining layer; and
removing the sacrificial layer, so that the separator has a first undercut at a lower portion of the separator in a direction to a center of the first pixel electrode.

32. The method of claim 31, further comprising:
forming a first common layer including a 1^{st}-1^{st} common layer and 1^{st}-2^{nd} common layer spaced apart from the 1^{st}-1^{st} common layer, the 1^{st}-1^{st} common layer being disposed on the first pixel electrode and the 1^{st}-2^{nd} common layer being disposed on the separator;
forming a 1^{st}-1^{st} emission layer on the 1^{st}-1^{st} common layer;
forming a second common layer including a 2^{nd}-1^{st} common layer and a 2^{nd}-2^{nd} common layer spaced apart from the 2^{nd}-1^{st} common layer, the 2^{nd}-1^{st} common layer being disposed on the 1^{st}-1^{st} emission layer and the 2^{nd}-2^{nd} common layer being disposed on the 1^{st}-2^{nd} common layer;
forming a 1^{st}-2^{nd} emission layer on the 2^{nd}-1^{st} common layer; and
forming an opposite electrode overlapping the 1^{st}-2^{nd} emission layer and the separator in a plan view.

33. The method of claim 32, further comprising:
forming a third common layer including a 3^{rd}-1^{st} common layer and a 3^{rd}-2^{nd} common layer spaced apart from the 3^{rd}-1^{st} common layer, the 3^{rd}-1^{st} common layer being disposed on the 1^{st}-2^{nd} emission layer and the 3^{rd}-2^{nd} common layer being disposed on the 2^{nd}-2^{nd} common layer,
wherein the forming of the opposite electrode comprises forming the opposite electrode on the third common layer.

34. The method of claim 32, wherein
the 2^{nd}-1^{st} common layer comprises a first charge generating layer, and the 2^{nd}-2^{nd} common layer comprises a second charge generating layer and the second charge generating layer and the first charge generating layer include a same material.

35. The method of claim 32, wherein
the forming of the opposite electrode comprises forming the opposite electrode integrally formed as a single body with a thickness greater than a thickness of the sacrificial layer.

36. The method of claim 31, wherein
the forming of the sacrificial layer comprises forming an IGZO layer, an ITO layer, or a ZTO layer.

37. The method of claim 31, wherein
the forming of the separator comprises simultaneously forming the separator and a spacer having a lower surface, an entire area of the lower surface of the spacer contacting the pixel-defining layer.
